(19) United States
(12) Patent Application Publication
(10) Pub. No.: US 2025/0079250 A1
(43) Pub. Date: Mar. 6, 2025

(54) SEMICONDUCTOR PACKAGE AND METHOD OF MANUFACTURING THE SEMICONDUCTOR PACKAGE

(71) Applicant: Samsung Electronics Co., Ltd., Suwon-si (KR)

(72) Inventors: Yeongkwon Ko, Suwon-si (KR); Unbyoung Kang, Suwon-si (KR); Soyeon Kwon, Suwon-si (KR); Kuyoung Kim, Suwon-si (KR)

(21) Appl. No.: 18/810,742

(22) Filed: Aug. 21, 2024

(30) Foreign Application Priority Data
Sep. 4, 2023 (KR) 10-2023-0116671
Sep. 25, 2023 (KR) 10-2023-0128303

(51) Int. Cl. H01L 23/31; H01L 23/00; H01L 23/48; H01L 25/18; H10B 80/00

(52) U.S. Cl. CPC H01L 23/3135; H01L 25/18; H10B 80/00; H01L 23/481; H01L 24/16; H01L 24/17; H01L 24/32; H01L 24/33; H01L 24/73; H01L 2224/16146; H01L 2224/17181; H01L 2224/32145; H01L 2224/33181; H01L 2224/73204

(57) ABSTRACT

A semiconductor package includes a substrate structure, a plurality of semiconductor chips sequentially stacked on the substrate structure, a molding member on the substrate structure and surrounding side surfaces of the plurality of semiconductor chips, the molding member including a first material, and a first reforming portion in a side portion of the molding member, and extending horizontally in the side portion of the molding member to have a predetermined width from an outer side surface of the molding member. The first reforming portion may include a second material that is more brittle than the first material.

### CROSS-REFERENCE TO RELATED APPLICATIONS

This application claims priority under 35 U.S.C. § 119 to Korean Patent Application Nos. 10-2023-0116671 and 10-2023-0128303, filed on Sep. 4, 2023 and filed on Sep. 25, 2023, respectively, in the Korean Intellectual Property Office (KIPO), the contents of which are herein incorporated by reference in their entirety.

### BACKGROUND OF THE INVENTION

Example embodiments relate to a semiconductor package and a method of manufacturing the semiconductor package. More particularly, example embodiments relate to a wafer level package having a chip-on-wafer (COW) packaging configuration which mounts a semiconductor chip on a wafer and a manufacturing method thereof.

In a wafer level package (WLP) process using chip on wafer (COW) technology, a molding process is performed to cover individual chips stacked on a wafer with EMC (Epoxy Molding Compound) and then a sawing process is performed to individualize each package. The sawing process uses a blade that rotates at a high speed to individualize each package. In the sawing process, a relatively high processing load occurs while cutting the EMC and the wafer, which increases the consumption of the blade and causes warpage in the blade and the package. Accordingly, there is a problem in that a slant cut in which a cutting surface appears diagonally occurs due to the high processing load, and as a result, a probability of collision between chips increases.

### SUMMARY OF THE INVENTION

Example embodiments provide a semiconductor package capable of reducing a processing load that occurs during a sawing process.

Example embodiments provide a method of manufacturing the semiconductor package.

According to example embodiments, a semiconductor package includes a substrate structure; a plurality of semiconductor chips sequentially stacked on the substrate structure; a molding member on the substrate structure and surrounding side surfaces of the plurality of semiconductor chips, the molding member including a first material; and a first reforming portion in a side portion of the molding member, and extending horizontally in the side portion of the molding member to have a predetermined width from an outer side surface of the molding member, wherein the first reforming portion includes a second material that is more brittle than the first material.

According to example embodiments, a semiconductor package includes a substrate structure having a first mounting region and a second mounting region that is spaced apart from the first mounting region along a first horizontal direction; a first electronic device stacked on the first mounting region of the substrate structure; a second electronic device stacked on the second mounting region of the substrate structure; a molding member on the substrate structure and surrounding outer surfaces of the first electronic device and outer surfaces of the second electronic device, the molding member including a first material; and a first reforming portion in a side portion of the molding member, and extending horizontally in the side portion of the molding member to have a predetermined width from an outer side surface of the molding member, wherein the first reforming portion includes a second material that is more brittle than the first material.

According to example embodiments, a semiconductor package includes a substrate structure; a plurality of semiconductor chips sequentially stacked on the substrate structure; a molding member on the substrate structure and surrounding side surfaces of the plurality of semiconductor chips, the molding member including a first material; a first reforming portion in a side portion of the molding member, and extending horizontally in the side portion of the molding member to have a predetermined width from an outer side surface of the molding member; and a second reforming portion in the side portion of the molding member and spaced apart from the first reforming portion along a vertical direction so that the second reforming portion is closer to the substrate structure than the first reforming portion, the second reforming portion extending horizontally in the side portion of the molding member to have the predetermined width from the outer side surface of the molding member, wherein the first reforming portion and the second reforming portion include a second material that is more brittle than the first material.

According to example embodiments, in a method of manufacturing a semiconductor package, a wafer is provided, the wafer having a plurality of die regions respectively including a first semiconductor chip and a scribe lane region excluding the plurality of die regions. A plurality of second semiconductor chips are mounted on each of the plurality of die regions of the wafer. A molding member is formed, the molding member provided on an upper surface of the wafer to surround the plurality of second semiconductor chips. A central reforming portion is formed spaced apart from the upper surface of the molding member toward the wafer by irradiating a first laser having a first wavelength onto an edge portion of the molding member provided on the scribe lane region. A surface reforming portion is formed to be spaced apart from the central reforming portion and to expose at least a portion of the surface reforming portion from the upper surface of the molding member. And, the semiconductor package is individualized along the scribe lane region using a blade.

According to example embodiments, a semiconductor package includes a substrate structure, a plurality of semiconductor chips sequentially stacked on the substrate structure, a molding member on the substrate structure and surrounding side surfaces of the plurality of semiconductor chips, the molding member including a first material; and a first reforming portion provided on at least a portion of an outer side surface of the molding member, and extending horizontally along the portion of the outer side surface of the molding member to have a predetermined width from the outer side surface.

The first reforming portion includes a second material that is more brittle than the first material.

Accordingly, warpage of a blade and warpage of a package may be prevented by reducing a processing load imposed on the blade during the sawing process. Additionally, a consumption of the blade may be reduced. Thus, it may be possible to prevent slant cuts and a collision between chips.

### BRIEF DESCRIPTION OF THE DRAWINGS

FIG. 1 is a cross-sectional view illustrating a semiconductor package in accordance with example embodiments.

FIG. 2 is a plan view illustrating a semiconductor package in accordance with example embodiments.

FIGS. 3 to 17 are views illustrating a method of manufacturing a semiconductor package in accordance with example embodiments.

FIG. 18 is a cross-sectional view illustrating a semiconductor package in accordance with example embodiments.

FIG. 19 is a plan view illustrating the semiconductor package in FIG. 18.

FIG. 20 is a side view from the direction ‘J’ in FIG. 19.

FIG. 21 is a cross-sectional view taken along the line N-N′ in FIG. 20.

FIGS. 22 to 30 are views illustrating a method of manufacturing a semiconductor package in accordance with example embodiments.

FIG. 31 is a cross-sectional view illustrating a semiconductor package in accordance with example embodiments.

FIG. 32 is a plan view illustrating a semiconductor package in accordance with example embodiments.

FIGS. 33 to 40 are views illustrating a method of manufacturing a semiconductor package in accordance with example embodiments.

### DETAILED DESCRIPTION

Hereinafter, example embodiments will be explained in detail with reference to the accompanying drawings.

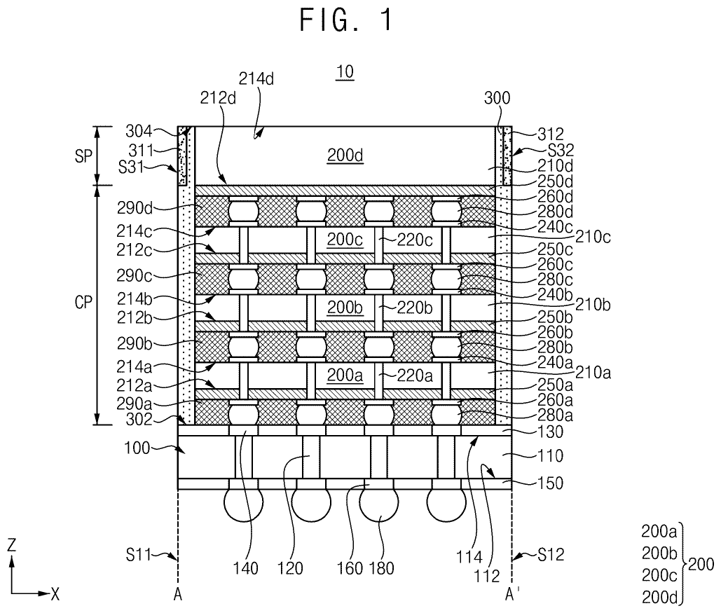

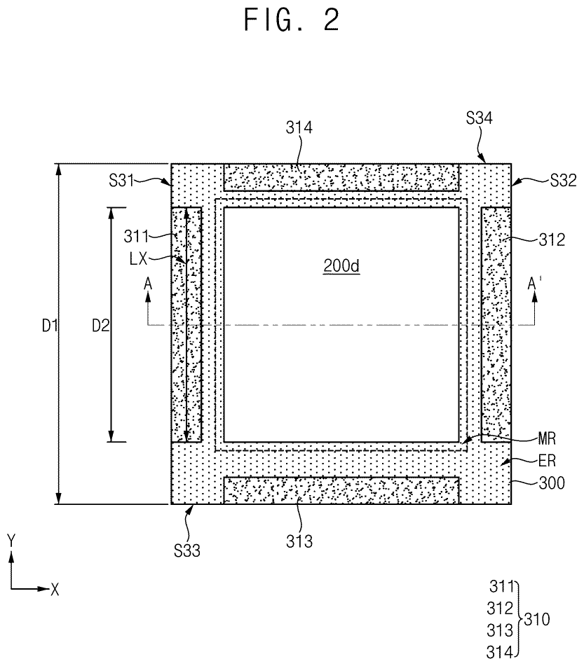

FIG. 1 is a cross-sectional view illustrating a semiconductor package in accordance with example embodiments. FIG. 2 is a plan view illustrating a semiconductor package in accordance with example embodiments. In particular, FIG. 1 is a cross-sectional view taken along the line A-A′ in FIG. 2.

Referring to FIGS. 1 and 2, a semiconductor package 10 may include a base chip 100, a plurality of semiconductor chips 200a, 200b, 200c, and 200d sequentially stacked on the base chip 100, and a molding member 300 provided on the base chip 100 to surround the plurality of semiconductor chips 200a, 200b, 200c, and 200d. It will be understood that “an element A surrounds an element B” (or similar language) as used herein means that the element A is at least partially around the element B but does not necessarily mean that the element A completely encloses the element B. Additionally, the semiconductor package 10 may further include a plurality of external connection members 180 and a plurality of conductive connection members 280 (280a, 280b, 280c, 280d). Additionally, the semiconductor package 10 may further include a plurality of surface reforming portions 310 (which may also be referred to as a plurality of reforming portions 310).

For example, the semiconductor package 10 may be a multi-chip package (MCP) including different types of semiconductor chips. For example, the semiconductor package may be a high bandwidth memory (HBM).

The base chip 100 and the plurality of semiconductor chips 200a, 200b, 200c, and 200d may be stacked on a package substrate such as a printed circuit board (PCB) or an interposer. As shown in FIG. 1, the semiconductor package 10 as a multi-chip package is illustrated as including five stacked semiconductor dies (chips) 100, 200a, 200b, 200c, and 200d. However, it will be understood that the present disclosure is not limited thereto.

In example embodiments, the base chip 100 may include base substrate 110, a plurality of conductive vias 120, an upper insulation layer 130, a plurality of upper pads 140, a lower insulation layer 150, a plurality of lower pads 160 and a plurality of external connection members 180. For example, the base chip 100 may be a semiconductor chip that serves as a buffer to connect and organize electrical signals between a plurality of memory chips and a controller chip. The base chip 100 and the elements included therein may also be referred to as a substrate structure 100.

The base chip 100 may extend along a first direction (X direction) and a second direction (Y direction) perpendicular to the first direction (X direction). The base chip 100 may have a first side portion S11 and a second side portion S12 extending in the second direction (Y direction) (i.e., into the page in FIG. 1). The base chip 100 may have a chip mounting region MR provided on a center portion and an edge region ER excluding the chip mounting region MR (see FIG. 2).

The base substrate 110 may have a lower surface 112 and an upper surface 114 opposed to each other. The lower surface 112 may be an active surface, and the upper surface 114 may be an inactive surface. Circuit patterns and cells may be formed on the lower surface 112 of the base substrate 110. For example, the base substrate 110 may be a single crystal silicon substrate. For example, the circuit patterns may include transistors, capacitors, diodes, etc. For example, the circuit patterns may constitute circuit elements. Accordingly, the base chip may be a semiconductor device with a plurality of circuit elements formed therein.

The plurality of conductive vias 120 may be provided to vertically penetrate (i.e., vertically extend in) the base substrate 110 from the lower surface 112 to the upper surface 114 of the base substrate 110. For example, the plurality of conductive vias 120 may be through silicon via (TSV). For example, the plurality of conductive vias 120 may be provided on the chip mounting region MR.

The upper insulation layer 130 may be provided on the upper surface 114 of the base substrate 110. For example, the upper insulation layer 130 may expose an end portion of each of the plurality of conductive vias 120 to be on (e.g., to cover) the upper surface 114 of the base substrate 110.

The plurality of upper pads 140 may be provided on the upper surface 114 of the base substrate 110 to form an array along the first and second directions (X and Y directions). For example, the plurality of upper pads 140 may be provided within the upper insulation layer 130, and at least a portion of each of the plurality of upper pads 140 may be exposed from the upper insulation layer 130. The plurality of upper pads 140 may be in contact with end portions (e.g., upper end portions) of the plurality of conductive vias 120, respectively, and electrically connected to the end portions of the plurality of conductive vias 120, respectively. For example, the plurality of upper pads 140 may be conductive pads containing a metal material. For example, the plurality of upper pads 140 may be provided on the chip mounting region MR.

The lower insulation layer 150 may be provided on the lower surface 112 of the base substrate 110. For example, the lower insulation layer 150 may be on (e.g., may cover) the lower surface 112 of the base substrate 110 and expose an end portion of each of the plurality of conductive vias 120.

The plurality of lower pads 160 may be provided on the lower surface 112 of the base substrate 110 to form an array along the first and second directions (X and Y directions). For example, the plurality of lower pads 160 may be provided within the lower insulation layer 150 and at least a portion of each of the plurality of lower pads 160 may be exposed from the lower insulation layer 150. The plurality of lower pads 160 may be in contact with end portions (e.g., lower end portions) of the plurality of conductive vias 120, respectively, and electrically connected to the end portions of the plurality of conductive vias 120, respectively. For example, the plurality of lower pads 160 may be conductive pads containing a metal material. For example, the plurality of lower pads 160 may be provided in the chip mounting region MR.

The plurality of external connection members 180 may be provided on the plurality of lower pads 160 to be electrically connected to the plurality of lower pads 160, respectively. For example, the plurality of external connection members 180 may include solder bumps.

In example embodiments, the plurality of semiconductor chips 200 (200a, 200b, 200c, 200d) may include a substrate 210 (210a, 210b, 210c, 210d), a plurality of through vias 220 (220a, 220b, 220c), a plurality of backside pads 240 (240a, 240b, 240c), a front insulation layer 250 (250a, 250b, 250c, 250d), a plurality of frontside pads 260 (260a, 260b, 260c, 260d), a plurality of conductive connection members 280 (280a, 280b, 280c, 280d), and an adhesive layer 290 (290a, 290b, 290c, 290d). For example, the plurality of semiconductor chips 200 may be an electronic device in which memory chips such as DRAM are stacked and electrically connected to each other.

The plurality of semiconductor chips 200 may be stacked on the chip mounting region MR of the base chip 100. For example, the plurality of semiconductor chips 200 may be sequentially stacked on the chip mounting region MR of the base chip 100 along a third direction (Z direction) perpendicular to the first direction (X direction) and the second direction (Y direction).

The plurality of semiconductor chips 200 may include first to fourth semiconductor chips 200a, 200b, 200c, and 200d. In some embodiments, the first to fourth semiconductor chips 200a, 200b, 200c, and 200d may be substantially the same or similar to each other. Accordingly, identical or similar components are indicated by identical or similar reference numerals, and repeated descriptions of the same components may be omitted.

The first semiconductor chip 200a may include a first substrate 210a, a plurality of first through vias 220a, a plurality of first backside pads 240a, a first front insulation layer 250a, a plurality of first frontside pads 260a, and a plurality of first conductive connection members 280a. Additionally, the first semiconductor chip 200a may further include a first adhesive layer 290a.

The first semiconductor chip 200a may be mounted on the base chip 100 via the first conductive connection members 280a respectively provided between the plurality of first frontside pads 260a and the plurality of upper pads 140. For example, the first conductive connection members 280a may include conductive bumps such as solder bumps.

The first substrate 210a may have a first surface 212a and a second surface 214a opposed to each other. The first surface 212a may be an active side, and the second surface 214a may be an inactive side. Circuit patterns and cells may be formed on the first surface 212a of the first substrate 210a. For example, the first substrate 210a may be a single crystal silicon substrate. The circuit patterns may include transistors, capacitors, diodes, etc. The circuit patterns may constitute circuit elements. Accordingly, the first semiconductor chip 200a may be a semiconductor device with a plurality of circuit elements formed therein.

The plurality of first through vias 220a may be provided to vertically penetrate (i.e., vertically extend in) the base substrate 110 from the first surface 212a of the first substrate 210a to the second surface 214a of the first substrate 210a. For example, the plurality of first through vias 220a may be through silicon vias (TSVs). For example, the plurality of first through vias 220a may be provided in the chip mounting region MR.

The plurality of first backside pads 240a may be provided on the second surface 214a of the first substrate 210a to form an array along the first and second directions (X and Y directions). The plurality of first backside pads 240a may be in contact with end portions (e.g., upper end portions) of the plurality of first through vias 220a, respectively, and electrically connected to the end portions of the plurality of first through vias 220a, respectively. For example, the plurality of first backside pads 240a may be conductive pads containing a metal material.

The first front insulation layer 250a may be provided on the first surface 212a of the first substrate 210a. For example, the first front insulation layer 250a may expose an end portion (e.g., a lower end portion) of each of the plurality of first through vias 220a and be on (e.g., cover) the first surface 212a of the first substrate 210a.

The plurality of first frontside pads 260a may be provided on the first front insulation layer 250a to form an array along the first and second directions (X and Y directions). For example, the plurality of first frontside pads 260a may be electrically connected to a plurality of front wirings (not shown) provided in the lower insulation layer 150. The plurality of first frontside pads 260a may be in contact with end portions (e.g., lower end portions) of the plurality of first through vias 220a, respectively, and electrically connected to the end portions of the plurality first through vias 220a, respectively. For example, the plurality of first frontside pads 260a may be conductive pads containing a metal material.

The plurality of first conductive connection members 280a may be provided on the plurality of first frontside pads 260a, respectively, and may be electrically connected to the plurality of first frontside pads 260a, respectively. For example, the plurality of first conductive connection members 280a may include solder bumps.

The first adhesive layer 290a may be provided between the base chip 100 and the first semiconductor chip 200a to be on (e.g., to cover) the plurality of conductive connection members 280a. For example, the first adhesive layer 290a may include a non-conductive film (NCF). Alternatively, the first adhesive layer 290a may include an epoxy molding compound (EMC).

The second semiconductor chip 200b may be mounted on the first semiconductor chip 200a. For example, the second semiconductor chip 200b may be mounted on the first semiconductor chip 200a via a plurality of second conductive connection members 280b provided between the plurality of first backside pads 240a and a plurality of second frontside pads 260b.

The third semiconductor chip 200c may be mounted on the second semiconductor chip 200b. For example, the third semiconductor chip 200c may be mounted on the second semiconductor chip 200b via a plurality of third conductive connection members 280c provided between the plurality of second backside pads 240b and a plurality of third frontside pads 260c.

The fourth semiconductor chip 200d may include a fourth substrate 210d, a fourth front insulation layer 250d, a plurality of fourth frontside pads 260d, and a plurality of fourth conductive connection members 280d. Additionally, the fourth semiconductor chip 200d may further include a fourth adhesive layer 290d.

The fourth semiconductor chip 200d may be mounted on the third semiconductor chip 200c. For example, the fourth semiconductor chip 200d may be mounted on the third semiconductor chip 200c via a plurality of fourth conductive connection members 280d respectively provided between the plurality of third backside pads 240c and a plurality of fourth frontside pads 260d.

In example embodiments, the molding member 300 may be provided on an edge region ER of the base chip 100 to be on (e.g., to surround) the plurality of semiconductor chips 200. For example, the molding member 300 may be on (e.g., may cover) a plurality of side surfaces of each of the plurality of semiconductor chips 200, and may expose a second surface 214d of the fourth semiconductor chip 200d, which is an uppermost semiconductor chip. In some other embodiments, the molding member 300 may be on (e.g., may cover) the second surface 214d of the fourth semiconductor chip 200d. For example, the molding member 300 may include an epoxy molding compound (EMC).

The molding member 300 may have a lower surface 302 in contact with the base chip 100 and an upper surface 304 facing the lower surface 302. The molding member 300 may provide first to fourth side portions S31, S32, S33, and S34 extending in the third direction (Z direction) to connect between the upper surface 304 and the lower surface 302. The first and second side portions S31 and S32 may have a first length D1 along the second direction (Y direction). Additionally, the third and fourth side portions S33 and S34 may have a first length D1 along the first direction (X direction).

The molding member 300 may have a surface portion SP including the upper surface 304 and a central portion CP excluding the surface portion SP.

The molding member 300 may include a plurality of surface reforming portions 310 provided in each of the first to fourth side portions S31, S32, S33, and S34, and at least a portion of each of the plurality of surface reforming portions 310 may be exposed from a respective one of the first to fourth side portions S31, S32, S33, and S34. As used herein, “an element A is exposed from an element B” (or similar language) means that the element A is not covered by the element B but does not necessarily preclude other elements from being on (or covering) the element A. For example, at least a portion of each of the plurality of surface reforming portions 310 may be exposed from the upper surface 304 of the molding member 300 and may be provided in the surface portion SP. For example, at least a portion of each of the plurality of surface reforming portions 310 may be coplanar with the upper surface 304 of the molding member 300. For example, the plurality of surface reforming portions 310 may include a material that is more brittle than the molding member 300. The brittleness may be the property of being easily broken when an external force is applied to a specific material. For example, as used herein, “a first material is more brittle than a second material” (or similar language) may mean that the first material is more easily broken than the second material when an external force is applied to the first material compared to when the external force is applied to the second material. While the plurality of surface reforming portions 310 are provided in the molding member 300, the plurality of surface reforming portions 310 may include the material that is more brittle than that of the molding member 300, and thus it will be appreciated that the plurality of surface reforming portions 310 may be described herein as separate elements from the molding member 300.

The plurality of surface reforming portions 310 may include first to fourth surface reforming portions 311, 312, 313, and 314.

The first to fourth surface reforming portions 311, 312, 313, and 314 may be provided in the first to fourth side portions S31, S32, S33, and S34, respectively. For example, the first to fourth surface reforming portions 311, 312, 313, and 314 may be exposed from the first to fourth side portions S31, S32, S33, and S34, respectively. The first to fourth surface reforming portions 311, 312, 313, and 314 may extend horizontally in the first to fourth side portions S31, S32, S33, and S34, respectively, to have a predetermined width from a respective outer side surface of the molding member 300. For example, the predetermined width of the first and second surface reforming portions 311 and 312 may be taken in the first direction (X direction), and the predetermined width of the third and fourth surface reforming portions 313 and 314 may be taken in the second direction (Y direction). For example, each of the first to fourth surface reforming portions 311, 312, 313, and 314 may have a side surface that is coplanar with a respective outer side surface of the molding member 300. Each of the first to fourth surface reforming portions 311, 312, 313, and 314 may be spaced apart from the plurality of semiconductor chips 200 by a predetermined distance.

The first to fourth surface reforming portions 311, 312, 313, and 314 may each have a longitudinal axis LX passing through the center thereof parallel to a respective one of the first to fourth side portions S31, S32, S33, and S34. For example, the first surface reforming portion 311 may have a longitudinal axis LX that is parallel to the first side portion S31 and passes through the center (e.g., a center point) of the first surface reforming portion 311.

The longitudinal axis LX may have a second length D2. For example, the second length D2 may be less than or equal to a first length D1 of each of the first to fourth side portions S31, S32, S33, and S34. For example, when the second length D2 and the first length D1 are the same, the first to fourth surface reforming portions 311, 312, 313, and 314 may be connected to each other to surround the first to fourth side portions S31, S32, S33, and S34.

As mentioned above, the semiconductor package 10 may include a base chip 100, a plurality of semiconductor chips 200a, 200b, 200c, and 200d sequentially stacked on the base chip 100, and a molding member 300 provided on the base chip 100 to surround the plurality of semiconductor chips 200a, 200b, 200c, and 200d. Additionally, the semiconductor package 10 may further include a plurality of external connection members 180 and a plurality of conductive connection members 280. Additionally, the semiconductor package 10 may further include a plurality of surface reforming portions 310.

The plurality of surface reforming portions 310 may be provided in the plurality of side portions S31, S32, S33, and S34 of the molding member 300, respectively, and at least a portion of each of the plurality of surface reforming portions 310 may be exposed from a respective one of the plurality of side portions S31, S32, S33, and S34 of the molding member 300. Also, the plurality of the surface reforming portions 310 may include relatively brittle material.

Accordingly, warpage of a blade and warpage of a package may be prevented by reducing a processing load imposed on the blade during the sawing process. Additionally, a consumption of the blade may be reduced. Thus, it may be possible to prevent slant cuts and a collision between chips

Hereinafter, a method of manufacturing the semiconductor package 10 of FIG. 1 will be described.

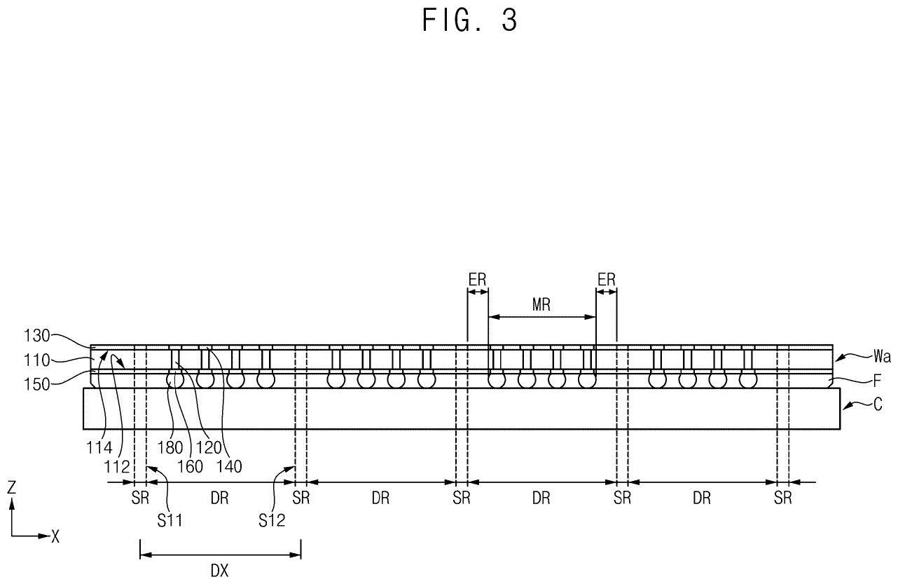

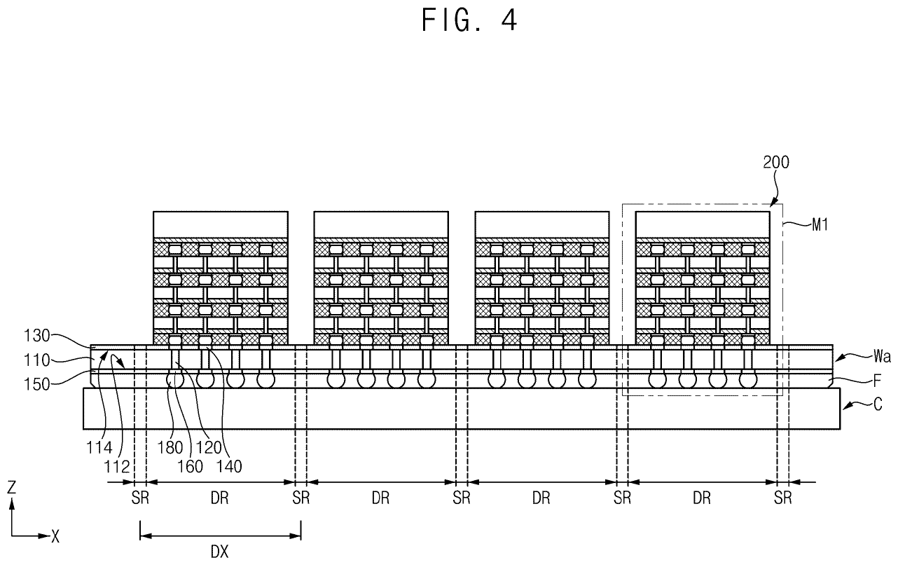

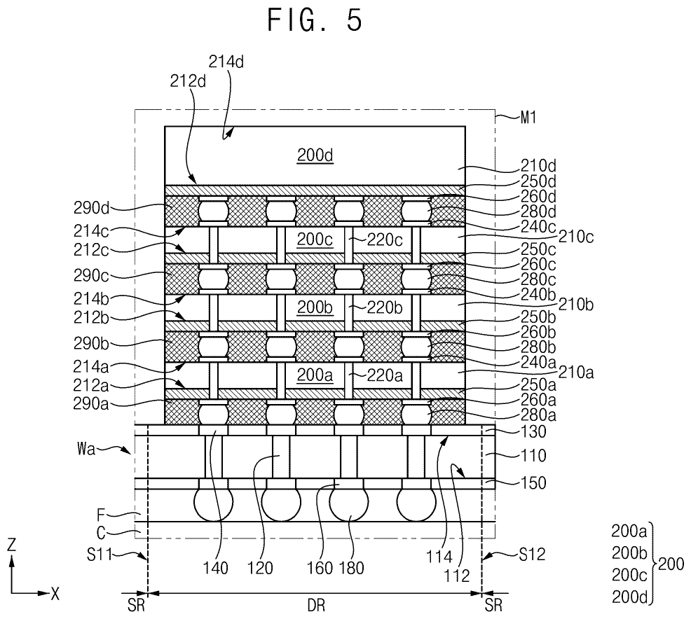

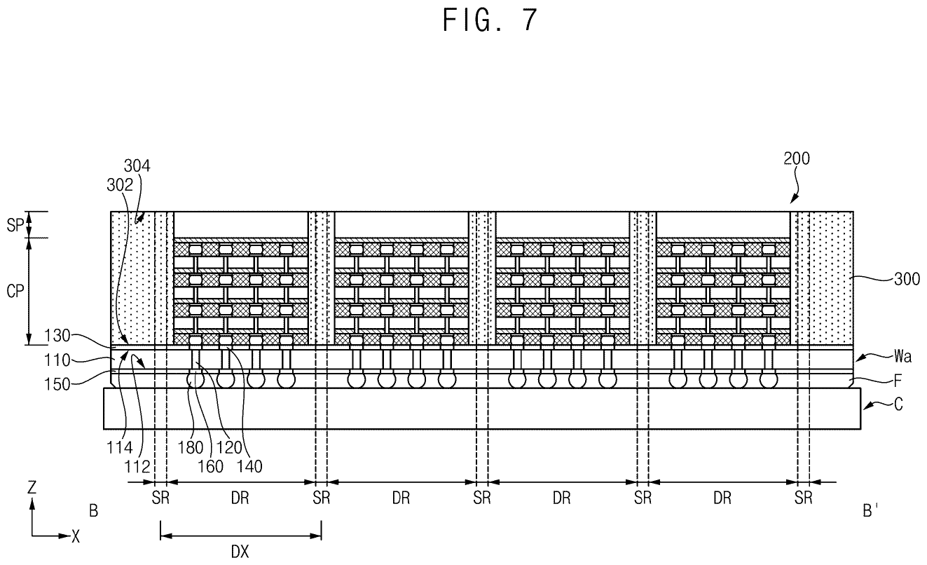

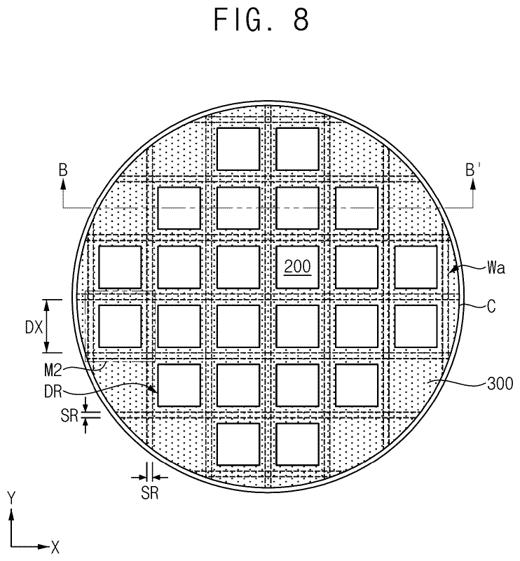

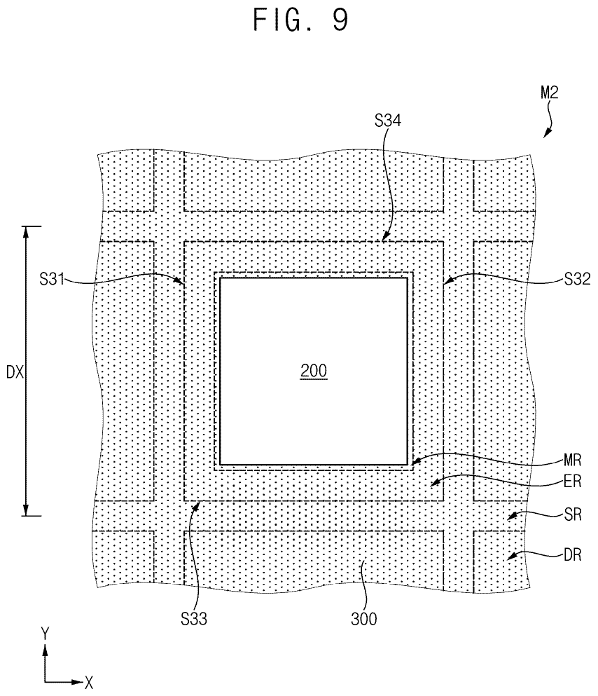

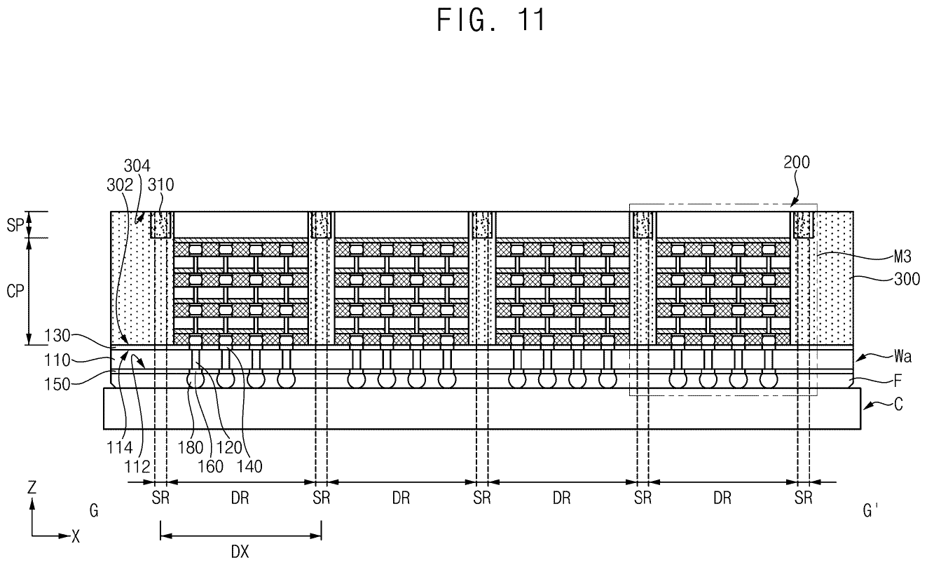

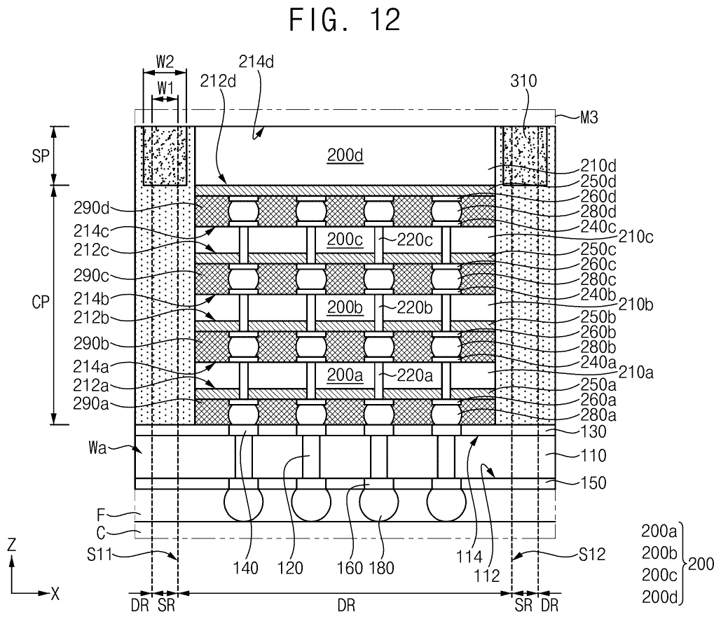

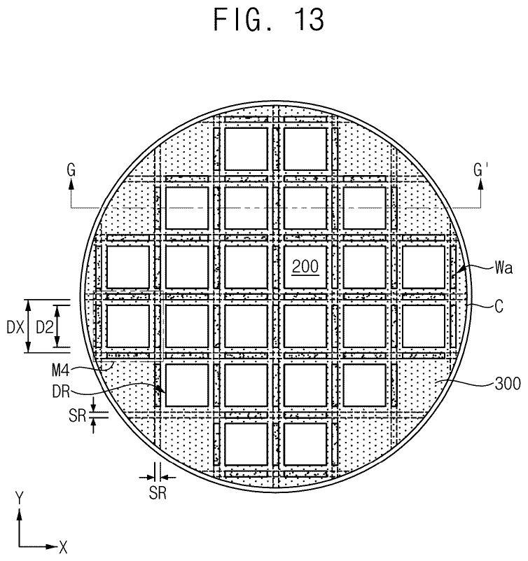

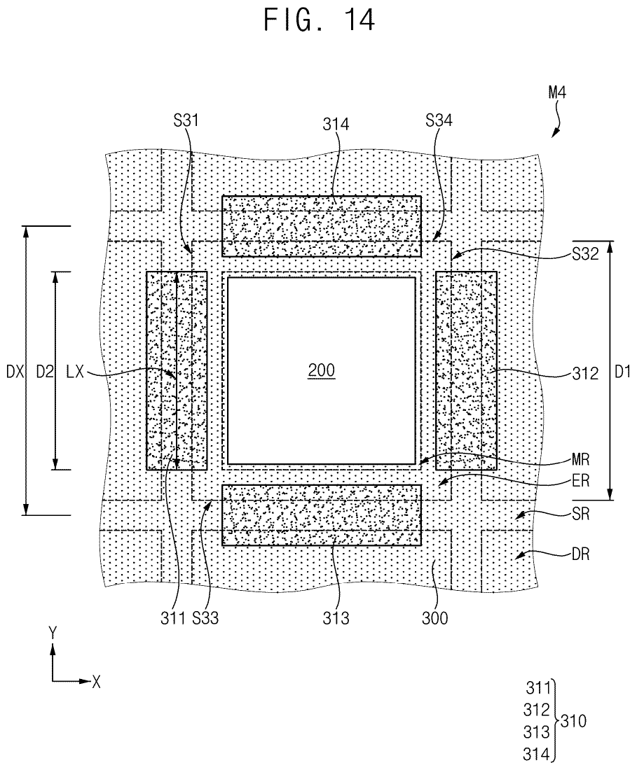

FIGS. 3 to 17 are views illustrating a method of manufacturing a semiconductor package in accordance with example embodiments. FIGS. 3-4, 6-7, 10-11, and 15-17 are cross-sectional views illustrating a method of manufacturing a semiconductor package in accordance with example embodiments. FIGS. 8 and 13 are plan views illustrating a method of manufacturing a semiconductor package in accordance with example embodiments. FIG. 5 is an enlarged cross-sectional view illustrating the portion ‘M1’ of FIG. 4. FIG. 7 is a cross-sectional view taken along the line B-B′ in FIG. 8. FIG. 9 is an enlarged cross-sectional view illustrating the portion ‘M2’ of FIG. 8. FIG. 12 is an enlarged cross-sectional view illustrating the portion ‘M3’ of FIG. 11. FIG. 11 is a cross-sectional view taken along the line G-G′ in FIG. 13. FIG. 14 is an enlarged cross-sectional view illustrating the portion ‘M4’ of FIG. 13.

Referring to FIG. 3, a wafer Wa in which a plurality of base chips (dies) are formed may be provided on a carrier substrate C. The wafer Wa may be attached to the carrier substrate C by an adhesive film F that protects a lower surface of the wafer Wa.

In example embodiments, the wafer Wa may include a base substrate 110 having a lower surface 112 and an upper surface 114 opposite to the lower surface 112. The base substrate 110 may include a die region DR in which integrated circuits are formed and a scribe lane region SR surrounding the die region DR. Later, the base substrate 110 may be cut along the scribe lane region SR that separates the plurality of die regions DR of the wafer Wa through a sawing process to be individualized into a plurality of base chips. For example, the plurality of base chips may include a buffer die as a processor that controls memory devices.

The die region DR where the base chips are formed may extend along a first direction (X direction) and a second direction (Y direction) perpendicular to the first direction (X direction), and may have a first side portion S11 and a second side portion S12 extending in the second direction (Y direction) (i.e., into the page in FIG. 3). The die region DR may include a chip mounting region MR provided in a center portion and an edge region ER excluding the chip mounting region MR.

The lower surface 112 of the base substrate 110 may be an active surface, and the upper surface 114 may be an inactive surface. Circuit patterns and cells may be formed on the lower surface 112 of the base substrate 110. For example, the base substrate 110 may be a single crystal silicon substrate. The circuit patterns may include transistors, capacitors, diodes, etc. The circuit patterns may constitute circuit elements.

The plurality of conductive vias 120 may be provided to vertically penetrate (i.e., vertically extend in) the base substrate 110 from the lower surface 112 to the upper surface 114 of the base substrate 110. For example, the plurality of conductive vias 120 may be a through silicon via (TSV). For example, the plurality of conductive vias 120 may be provided in the chip mounting region MR.

The upper insulation layer 130 may be provided on the upper surface 114 of the base substrate 110. For example, the upper insulation layer 130 may be on (e.g., may cover) the upper surface 114 of the base substrate 110 to expose one end of each of the plurality of conductive vias 120.

The plurality of upper pads 140 may be provided on the upper surface 114 of the base substrate 110 to form an array along the first and second directions (X and Y directions). For example, the plurality of upper pads 140 may be provided within the upper insulation layer 130, and at least a portion of each of the plurality of upper pads 140 may be exposed from the upper insulation layer 130. The plurality of upper pads 140 may be in contact with end portions of the plurality of conductive vias 120, respectively, to be electrically connected to the plurality of conductive vias 120, respectively. For example, the plurality of upper pads 140 may be conductive pads containing a metal material. For example, the plurality of upper pads 140 may be provided in the chip mounting region MR.

The lower insulation layer 150 may be provided on the lower surface 112 of the base substrate 110. For example, the lower insulation layer 150 may be on (e.g., may cover) the lower surface 112 of the base substrate 110 to expose an end portion of each of the plurality of conductive vias 120.

The plurality of lower pads 160 may be provided on the lower surface 112 of the base substrate 110 to form an array along the first and second directions (X and Y directions). For example, the plurality of lower pads 160 may be provided within the lower insulation layer 150, and at least a portion of each of the plurality of lower pads 160 may be exposed from the lower insulation layer 150. The plurality of lower pads 160 may be in contact with end portions of the plurality of conductive vias 120, respectively, to be electrically connected to the end portions of the plurality of conductive vias 120, respectively. For example, the plurality of lower pads 160 may be conductive pads containing a metal material. For example, the plurality of lower pads 160 may be provided in the chip mounting region MR.

The plurality of external connection members 180 are respectively provided on the plurality of lower pads 160 to be electrically connected to the plurality of lower pads 160, respectively. For example, the plurality of external connection members 180 may include solder bumps. The plurality of external connection members 180 may be surrounded (e.g., may be covered) by an adhesive film F provided between the wafer Wa and the carrier substrate C.

Referring to FIGS. 4 and 5, a plurality of semiconductor chips 200 may be mounted on the chip mounting region MR provided in the die region DR of the wafer Wa. For example, the plurality of semiconductor chips 200 may be provided on the chip mounting region MR of the die region DR of the wafer Wa in a chip on wafer (COW) manner in which individual semiconductor chips are sequentially stacked at each layer one at a time.

The plurality of semiconductor chips 200 may include a substrate 210, a plurality of through vias 220, a plurality of backside pads 240, a front insulation layer 250, a plurality of frontside pads 260, a plurality of conductive connection members 280, and an adhesive layer 290. For example, the plurality of semiconductor chips 200 may be an electronic device in which memory chips such as DRAM are stacked and electrically connected to each other.

For example, the plurality of semiconductor chips 200 may be sequentially stacked on the chip mounting region MR of the wafer Wa along a third direction (Z direction) perpendicular to the first direction (X direction) and the second direction (Y direction).

The plurality of semiconductor chips 200 may include first to fourth semiconductor chips 200a, 200b, 200c, and 200d. In some embodiments, the first to fourth semiconductor chips 200a, 200b, 200c, and 200d may be substantially the same or similar to each other. Accordingly, identical or similar components are indicated by identical or similar reference numerals, and repeated descriptions of the same components may be omitted.

The first semiconductor chip 200a may include a first substrate 210a, a plurality of first through vias 220a, a plurality of first backside pads 240a, a first front insulation layer 250a, a plurality of first frontside pads 260a, and a plurality of first conductive connection members 280a. Additionally, the first semiconductor chip 200a may further include a first adhesive layer 290a.

The first semiconductor chip 200a may be mounted on the base chip 100 via the first conductive connection members 280a respectively provided between the plurality of first frontside pads 260a and the plurality of upper pads 140. For example, the first conductive connection members 280a may include conductive bumps such as solder bumps.

The first substrate 210a may have a first surface 212a and a second surface 214a opposed to each other. The first surface 212a may be an active side, and the second surface 214a may be an inactive side. Circuit patterns and cells may be formed on the first surface 212a of the first substrate 210a. For example, the first substrate 210a may be a single crystal silicon substrate. The circuit patterns may include transistors, capacitors, diodes, etc. The circuit patterns may constitute circuit elements. Accordingly, the first semiconductor chip 200a may be a semiconductor device with a plurality of circuit elements formed therein.

The plurality of first through vias 220a may be provided to vertically penetrate (i.e., vertically extend in) the first substrate 210a from the first surface 212a of the first substrate 210a to the second surface 214a of the first substrate 210a. For example, the plurality of first through vias 220a may be through silicon vias (TSVs). For example, the plurality of first through vias 220a may be provided in the chip mounting region MR.

The plurality of first backside pads 240a may be provided on the second surface 214a of the first substrate 210a to form an array along the first and second directions (X and Y directions). The plurality of first backside pads 240a may be in contact with end portions of the plurality of first through vias 220a, respectively, and electrically connected to the end portions of the plurality of first through vias 220a, respectively. For example, the plurality of first backside pads 240a may be conductive pads containing a metal material.

The first front insulation layer 250a may be provided on the first surface 212a of the first substrate 210a. For example, the first front insulation layer 250a may expose end portions of the plurality of first through vias 220a and may be on (e.g., may cover) the first surface 212a of the first substrate 210a.

The plurality of first frontside pads 260a may be provided on the first front insulation layer 250a to form an array along the first and second directions (X and Y directions). For example, the plurality of first frontside pads 260a may be electrically connected to a plurality of front wirings (not shown) provided in the lower insulation layer 150. The plurality of first frontside pads 260a may be in contact with end portions of the plurality of first through vias 220a, respectively, and electrically connected to the end portions of the plurality of first through vias 220a, respectively. For example, the plurality of first frontside pads 260a may be conductive pads containing a metal material.

The plurality of first conductive connection members 280a may be provided on the plurality of first frontside pads 260a, respectively, and may be electrically connected to the plurality of first frontside pads 260a, respectively. For example, the plurality of first conductive connection members 280a may include solder bumps.

The first adhesive layer 290a may be provided between the wafer Wa and the first semiconductor chip 200a to be on (e.g., to cover) the plurality of conductive connection members 280a. For example, the first adhesive layer 290a may include a non-conductive film (NCF). Alternatively, the first adhesive layer 290a may include epoxy molding compound (EMC).

The second semiconductor chip 200b may be mounted on the first semiconductor chip 200a. For example, the second semiconductor chip 200b may be mounted on the first semiconductor chip 200a via a plurality of second conductive connection members 280b respectively provided between the plurality of first backside pads 240a and a plurality of second frontside pads 260b.

The third semiconductor chip 200c may be mounted on the second semiconductor chip 200b. For example, the third semiconductor chip 200c may be mounted on the second semiconductor chip 200b via a plurality of third conductive connection members 280c respectively provided between the plurality of second backside pads 240b and a plurality of third frontside pads 260c.

The fourth semiconductor chip 200d may include a fourth substrate 210d, a fourth front insulation layer 250d, a plurality of fourth frontside pads 260d, and a plurality of fourth conductive connection members 280d. Additionally, the fourth semiconductor chip 200d may further include a fourth adhesive layer 290d.

The fourth semiconductor chip 200d may be mounted on the third semiconductor chip 200c. For example, the fourth semiconductor chip 200d may be mounted on the third semiconductor chip 200c via a plurality of fourth conductive connection members 280d respectively provided between the plurality of third backside pads 240c and a plurality of fourth frontside pads 260d.

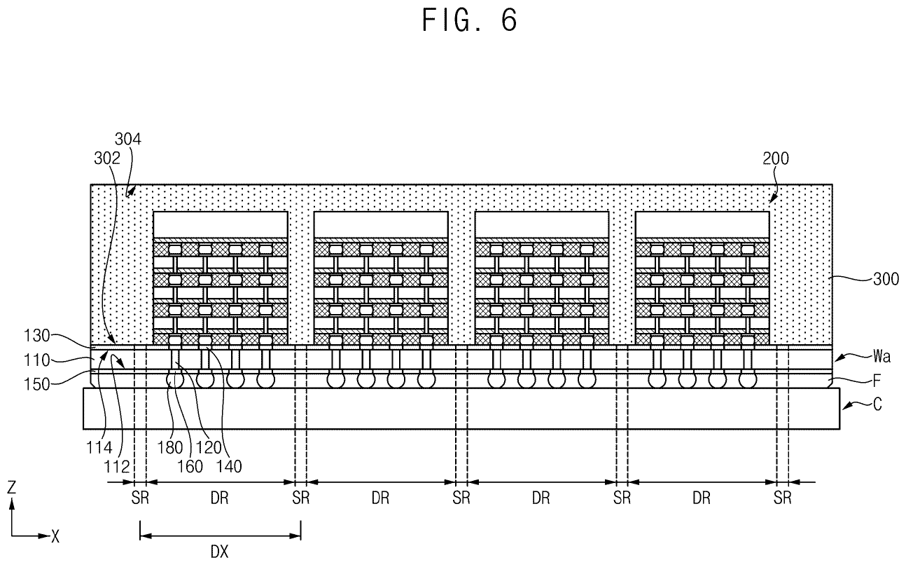

Referring to FIGS. 6 to 9, a molding member 300 may be formed on the upper surface of the wafer Wa to surround the plurality of semiconductor chips 200 mounted on each of the die regions of the wafer Wa. For example, the molding member 300 may include a thermosetting material that hardens when heat is applied. For example, the molding member 300 may include an epoxy molding compound (EMC). Thereafter, a cure process may be performed to harden the molding member 300, and a grinding process may be performed to remove a portion of the molding member 300 to expose a portion of the plurality of semiconductor chips 200.

The molding member 300 may be on (e.g., may cover) the upper surface of the wafer Wa excluding the chip mounting region MR. For example, the molding member 300 may be on (e.g., may cover) the edge region ER among the die region DR and the scribe lane region SR. The scribe lane region SR may be arranged to surround side portions of the plurality of semiconductor chips 200. For example, a plurality of scribe lane regions SR may be sequentially arranged along the first and second directions (X and Y directions) on the upper surface of the wafer Wa to surround the square-shaped die region DR, and may be spaced apart from each other by a constant distance. For example, a spacing distance between the scribe lane regions SR may be a first distance DX.

The molding member 300 may include first to fourth side portions S31, S32, S33, and S34 along the die region DR and a boundary line surrounding the die region DR. For example, the first and second side portions S31 and S32 may face each other (i.e., may oppose each other) with the die region DR in between, and may be parallel to the second direction (Y direction). Additionally, the third and fourth side portions S33 and S34 may face each other (i.e., may oppose each other) with the die region DR in between, and may be parallel to the first direction (X direction).

The molding member 300 may have a lower surface 302 in contact with the wafer Wa and an upper surface 304 facing (i.e., opposing) the lower surface 302. The molding member 300 may have a surface portion SP including the upper surface 304 and a central portion CP excluding the surface portion SP.

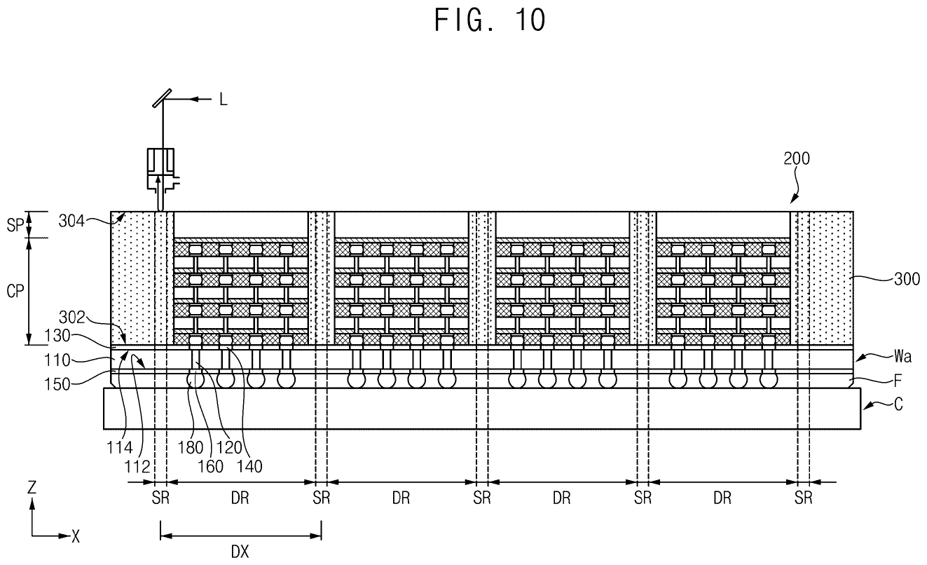

Referring to FIGS. 10 to 14, a laser process may be performed to reform a portion of the molding member 300 provided on the scribe lane region SR and the die region DR adjacent to the scribe lane region SR. The reforming process may be a process of changing the physical properties of a specific material by irradiating a laser. For example, the brittleness of an epoxy molding compound (EMC) may be increased by irradiating a laser on epoxy molding compound (EMC) that has been hardened by performing a cure process. The brittleness may be the property of being easily broken when an external force is applied to a specific material.

A plurality of surface reforming portions 310 may be formed by irradiating laser L to a portion of the molding member 300 provided on the scribe lane region SR and a portion of the die region DR adjacent to the scribe lane region SR.

The laser L may be concentrated light having a preset wavelength λ. For example, the preset wavelength λ may be set in consideration of physical properties of the molding member 300 and a depth at which the plurality of surface reforming portions 310 are formed. For example, when forming reforming portions in a surface of a cured epoxy molding compound (EMC), a short wavelength may be used because there is little need to transmit a cured epoxy molding compound (EMC). For example, when forming the plurality of surface reforming portions 310, the preset wavelength λ may be within a range of 360 nm to 530 nm.

As illustrated in FIG. 11, the plurality of surface reforming portions 310 may be provided in the surface portion SP, such that a portion of each of the plurality of surface reforming portions 310 is exposed from the upper surface 304 of the molding member 300 (i.e., is free of the upper surface 304 of the molding member 300 thereon).

As illustrated in FIG. 12, the plurality of surface reforming portions 310 may be formed on the scribe lane region SR and a portion of the die region DR adjacent to the scribe lane region SR. A width of the scribe lane region SR may have a first width W1. A width of each of the plurality of the surface reforming portions 310 may have a second width W2. For example, the second width W2 may be greater than or equal to the first width W1.

As illustrated in FIGS. 12 to 14, the plurality of surface reforming portions 310 may be formed in the surface portion SP of the molding member 300 to surround a portion of the molding member 300 provided on each of the plurality of the die regions DR.

For example, the portion of the molding member 300 provided on each of the plurality of the die regions DR may include the first to fourth side portions S31, S32, S33, and S34 which are in contact with the scribe lane region SR. Each of the first to fourth side portions S31, S32, S33, and S34 may have a first length D1. The plurality of surface reforming portions 310 may extend in and across the first to fourth side portions S31, S32, S33, and S34.

The plurality of surface reforming portions 310 may include first to fourth surface reforming portions 311, 312, 313, and 314. The first to fourth surface reforming portions 311, 312, 313, and 314 may extend in and across the first to fourth side portions S31, S32, S33, and S34 to extend to portions on the molding member 300 respectively provided on the plurality of die regions DR.

The first to fourth surface reforming portions 311, 312, 313, and 314 may each have a longitudinal axis LX passing through the center thereof parallel to a respective one of the first to fourth side portions S31, S32, S33, and S34. For example, the first surface reforming portion 311 may have a longitudinal axis LX that is parallel to the first side portion S31 and passes through the center (e.g., a center point) of the first surface reforming portion 311.

The longitudinal axis LX may have a second length D2. For example, the second length D2 may be less than or equal to the first distance DX, which is the spacing distance between the scribe lane regions SR. When the second length D2 and the first distance DX are the same, the plurality of surface reforming portions 310 may cover all of the scribe lane region SR. For example, the second length D2 may be less than or equal to the first length D1 of each of the first to fourth side portions S31, S32, S33, and S34. When the second length D2 and the first length D1 are the same, the first to fourth surface reforming portions 311, 312, 313, and 314 may be connected to each other to surround the first to fourth side portions S31, S32, S33, and S34.

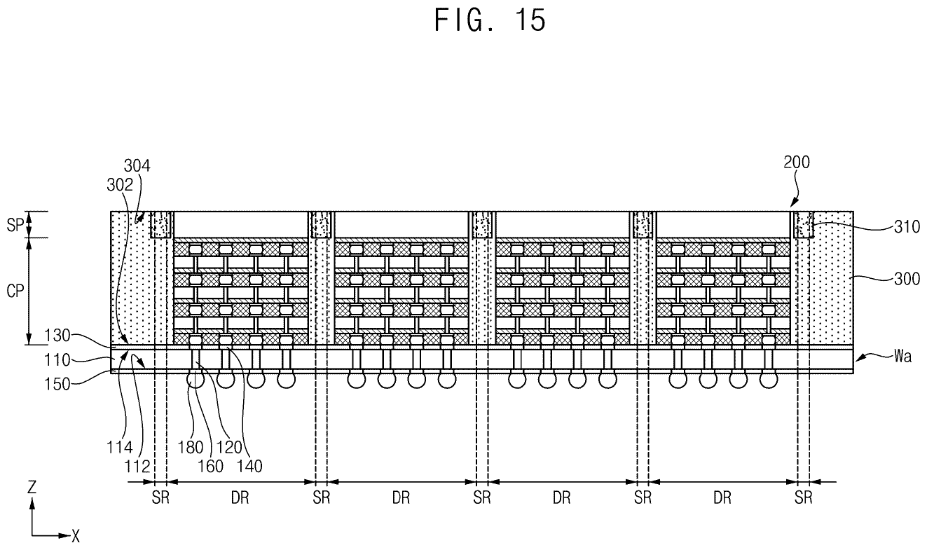

Referring to FIG. 15, the carrier substrate C may be removed from the wafer Wa, and the adhesive film F may be removed from the bottom of the wafer Wa.

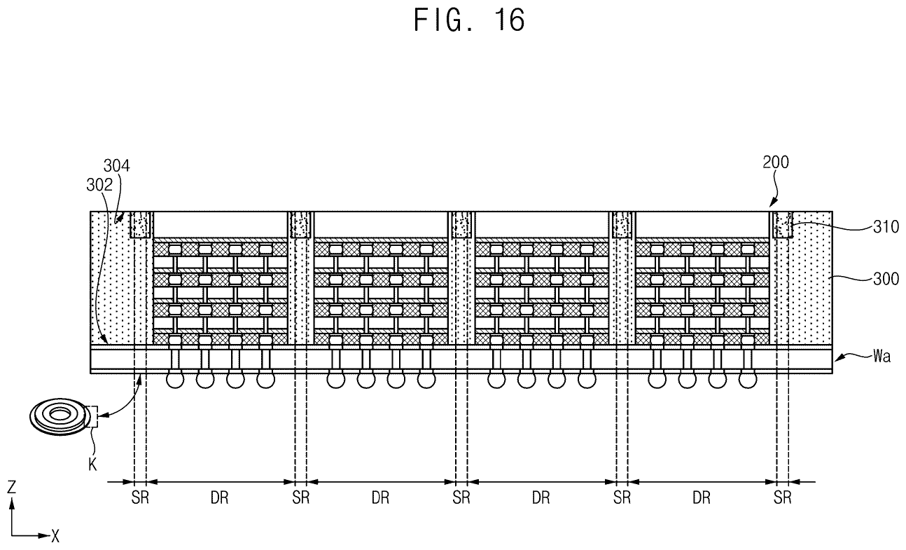

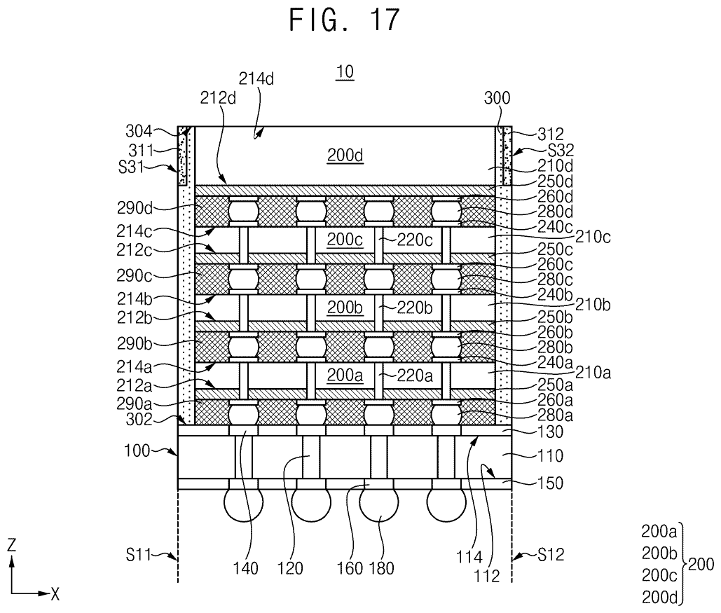

Referring to FIGS. 16 and 17, the semiconductor package 10 may be formed by individualizing the wafer to each package through a sawing process using a blade.

For example, the wafer Wa and the molding member 300 may be cut along the scribe lane region SR of the wafer Wa. In this case, the blade may include a kerf K that is configured to be in direct contact with the wafer Wa and the molding member 300. For example, the kerf K may refer to a width of a cut made by the blade, and the kerf K may correspond to a portion of the blade which contacts the wafer Wa and the molding member 300 while cutting (i.e., sawing) them.

A portion of the molding member 300 in contact with the kerf K may include a plurality of surface reforming portions 310. The plurality of surface reforming portions 310 may contain a relatively brittle material, so the plurality of surface reforming portions 310 may be easily cut by the blade. Accordingly, by reducing the processing load exerted on the blade during the sawing process, it may be possible to reduce blade consumption and prevent warpage of the blade and package. Additionally, the probability of collision between chips may be reduced by preventing slant cuts that is a phenomenon in which the cutting surface forms a diagonal shape due to processing load during the sawing process.

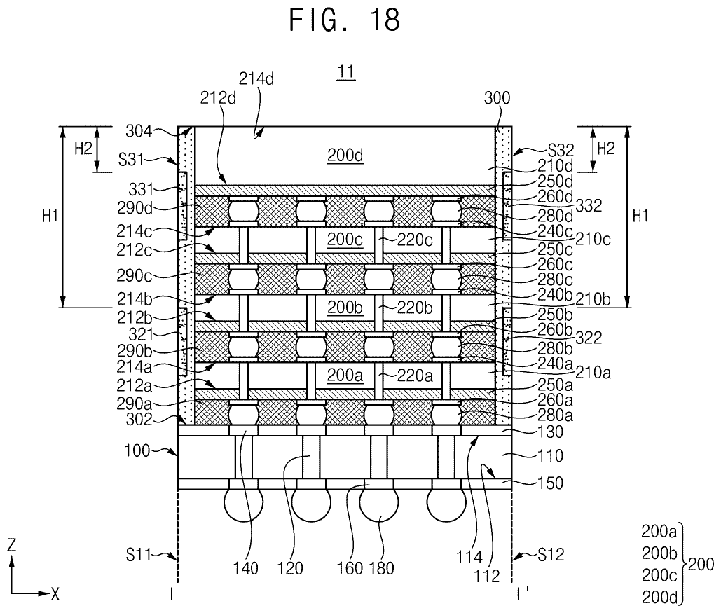

Hereinafter, a semiconductor package 11 in FIG. 18 will be described.

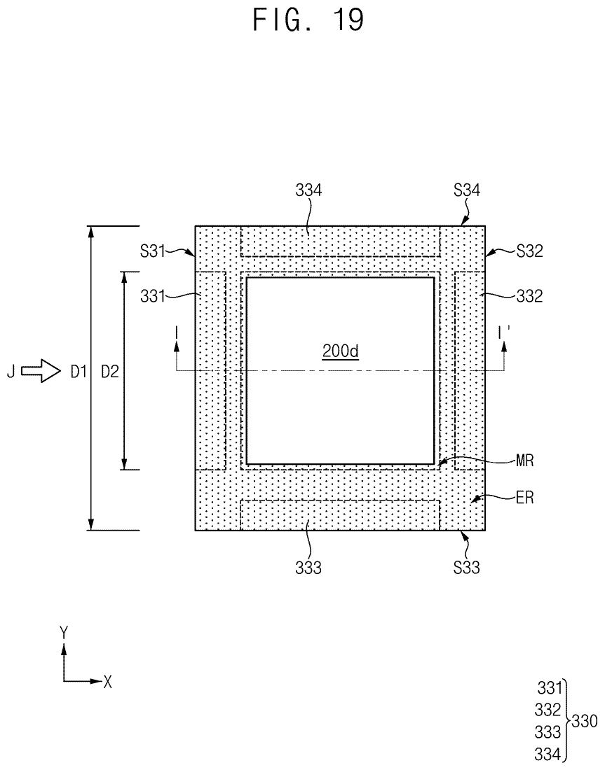

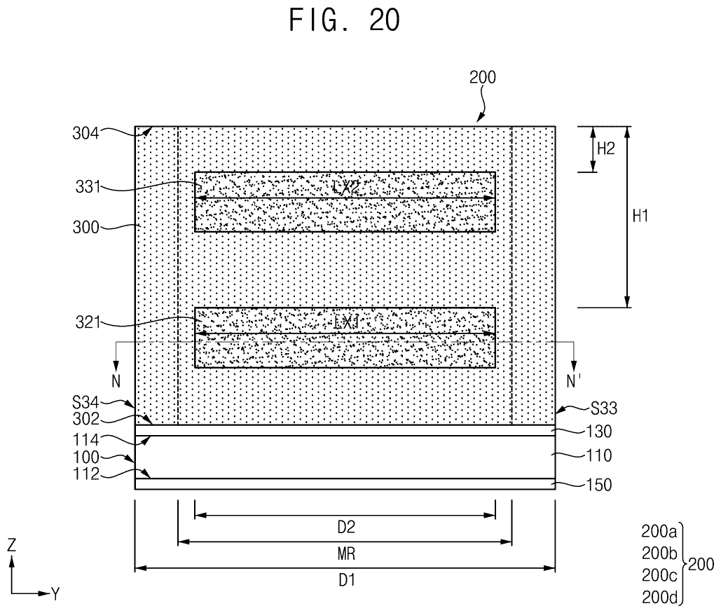

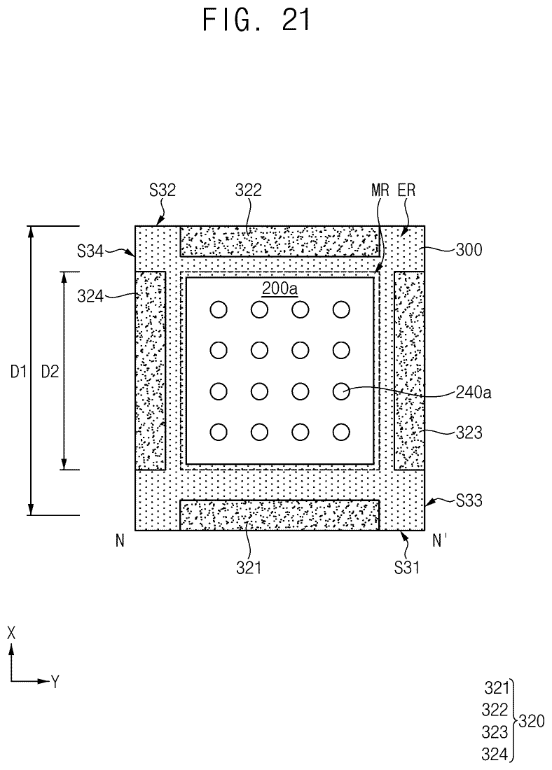

FIG. 18 is a cross-sectional view illustrating a semiconductor package in accordance with example embodiments. FIG. 19 is a plan view illustrating the semiconductor package in FIG. 18. FIG. 20 is a side view from the direction ‘J’ in FIG. 19. FIG. 21 is a cross-sectional view taken along the line N-N′ in FIG. 20. FIG. 18 is a cross-sectional view taken along the line I-I′ in FIG. 19.

Referring to FIGS. 18 to 21, a semiconductor package 11 may include a base chip 100, a plurality of semiconductor chips 200a, 200b, 200c, and 200d sequentially stacked on the base chip 100, and a molding member 300 provided on the base chip 100 to surround the plurality of semiconductor chips 200a, 200b, 200c, and 200d. Additionally, the semiconductor package 11 may further include a plurality of external connection members 180 and a plurality of conductive connection members 280. Additionally, the semiconductor package 11 may further include a plurality of first reforming portions 320 and a plurality of second reforming portions 330.

The semiconductor package 11 may be substantially the same as or similar to the semiconductor package 10 described above with reference to FIGS. 1 and 2 except for the plurality of first reforming portions 320 and the plurality of second reforming portions 330. Accordingly, the same components are indicated by the same reference numerals, and repeated descriptions of the same components are omitted.

In example embodiments, the molding member 300 may be provided on an edge region ER of the base chip 100 to surround the plurality of semiconductor chips 200. For example, the molding member 300 may be on (e.g., may cover) a plurality of side surfaces of each of the plurality of semiconductor chips 200, and may expose the second surface 214d of the fourth semiconductor chip 200d, which is an uppermost semiconductor chip. In some other embodiments, the molding member 300 may be on (e.g., may cover) the second surface 214d of the fourth semiconductor chip 200d. For example, the molding member 300 may include an epoxy molding compound (EMC).

The molding member 300 may have a lower surface 302 in contact with the base chip 100 and an upper surface 304 facing the lower surface 302. The molding member 300 may provide first to fourth side portions S31, S32, S33, and S34 extending in the third direction (Z direction) to connect between the upper surface 304 and the lower surface 302. The first and second side portions S31 and S32 may have a first length D1 along the second direction (Y direction). Additionally, the third and fourth side portions S33 and S34 may have a first length D1 along the first direction (X direction).

The molding member 300 may have the plurality of first reforming portions 320 and the plurality of second reforming portions 330.

For example, the plurality of first reforming portions 320 and the plurality of second reforming portions 330 may be provided in the first to fourth side portions S31, S32, S33 and S34 to expose at least a portion of a side surface thereof from a respective outer side surface of the molding member 300. For example, the plurality of first reforming portions 320 and the plurality of second reforming portions 330 may include a material that is more brittle than the molding member 300. The brittleness may be the property of being easily broken when an external force is applied to a specific material.

The plurality of first reforming portions 320 and the plurality of second reforming portions 330 may be spaced apart along the third direction (Z direction) toward the base chip 100 to have a predetermined distance (i.e., a predetermined depth) from the upper surface 304 of the molding member 300. For example, the plurality of first reforming portions 320 may be spaced apart from the upper surface 304 of the molding member 300 toward the base chip 100 by a first height H1. Additionally, the plurality of second reforming portions 330 may be spaced apart from the upper surface 304 of the molding member 300 toward the base chip 100 by a second height H2. For example, the first height H1 may be greater than the second height H2.

In some other embodiments, the plurality of second reforming portions 330 may not be spaced apart from the upper surface 304 of the molding member 300 in the third direction (Z direction). For example, at least a portion of an upper surface of the plurality of second reforming portions 330 may be exposed from the upper surface 304 of the molding member 300 (i.e., may be free of the upper surface 304 of the molding member 300 thereon). In this case, the second height (H2) may be ‘0’.

The plurality of first reforming portions 320 may include first to fourth lower reforming portions 321, 322, 323, and 324. The first to fourth lower reforming portions 321, 322, 323, and 324 may be provided in the first to fourth side portions S31, S32, S33, and S34, respectively. For example, the first to fourth lower reforming portions 321, 322, 323, and 324 may be exposed from the first to fourth side portions S31, S32, S33, and S34, respectively. The first to fourth lower reforming portions 321, 322, 323, and 324 may extend horizontally in the first to fourth side portions S31, S32, S33, and S34, respectively, to have a predetermined width from a respective outer side surface of the molding member 300. For example, the predetermined width of the first and second lower reforming portions 321 and 322 may be taken in the first direction (X direction), and the predetermined width of the third and fourth lower reforming portions 323 and 324 may be taken in the second direction (Y direction). For example, each of the first to fourth lower reforming portions 321, 322, 323, and 324 may have a side surface that is coplanar with a respective outer side surface of the molding member 300. Each of the first to fourth lower reforming portions 321, 322, 323, and 324 may be spaced apart from the plurality of semiconductor chips 200 by a predetermined distance.

The first to fourth lower reforming portions 321, 322, 323, and 324 may each have a first longitudinal axis LX1 passing through the center thereof parallel to a respective one of the first to fourth side portions S31, S32, S33, and S34 (see FIGS. 20 and 21). For example, the first lower reforming portion 321 may have a first longitudinal axis LX1 that is parallel to the first side portion S31 and passes through the center (e.g., a center point) of the first lower reforming portion 321.

The first longitudinal axis LX1 may have a second length D2. For example, the second length D2 may be less than or equal to a first length D1 of each of the first to fourth side portions S31, S32, S33, and S34. For example, when the second length D2 and the first length D1 are the same, the first to fourth lower reforming portions 321, 322, 323, and 324 may be connected to each other to surround the first to fourth side portions S31, S32, S33, and S34.

The plurality of second reforming portions 330 may include first to fourth upper reforming portions 331, 332, 333, and 334. The first to fourth upper reforming portions 331, 332, 333, and 334 may be provided in the first to fourth side portions S31, S32, S33, and S34, respectively. For example, the first to fourth upper reforming portions 331, 332, 333, and 334 may be exposed from the first to fourth side portions S31, S32, S33, and S34, respectively. The first to fourth upper reforming portions 331, 332, 333, and 334 may extend horizontally in the first to fourth side portions S31, S32, S33, and S34, respectively, to have a predetermined width from a respective outer side surface of the molding member 300. For example, the predetermined width of the first and second upper reforming portions 331 and 332 may be taken in the first direction (X direction), and the predetermined width of the third and fourth upper reforming portions 333 and 334 may be taken in the second direction (Y direction). For example, each of the first to fourth upper reforming portions 331, 332, 333, and 334 may have a side surface that is coplanar with a respective outer side surface of the molding member 300. Each of the first to fourth upper reforming portions 331, 332, 333, and 334 may be spaced apart from the plurality of semiconductor chips 200 by a predetermined distance. For example, the first to fourth upper reforming portions 331, 332, 333, and 334 may respectively overlap the first to fourth lower reforming portions 321, 322, 323, and 324 in the third direction (Z direction). As used herein, “an element A overlaps an element B in a Z direction” (or similar language) means that there is at least one line that extends in the Z direction and intersects both the elements A and B.

Each of the first to fourth upper reforming portions 331, 332, 333, and 334 may have a second longitudinal axis LX2 passing through the center thereof parallel to a respective one of the first to fourth side portions S31, S32, S33, and S34 (see FIGS. 19 and 20). For example, the first upper reforming portion 331 may have a second longitudinal axis LX2 that is parallel to the first side portion S31 and passes through the center (e.g., a center point) of the first upper reforming portion 331.

The second longitudinal axis LX2 may have a second length D2. For example, the second length D2 may be less than or equal to the first length D1 of each of the first to fourth side portions S31, S32, S33, and S34. For example, when the second length D2 and the first length D1 are the same, the first to fourth upper reforming portions 331, 332, 333, and 334 may be connected to each other to surround the first to fourth side portions S31, S32, S33, and S34.

Hereinafter, a method of manufacturing the semiconductor package 11 of FIG. 18 will be described.

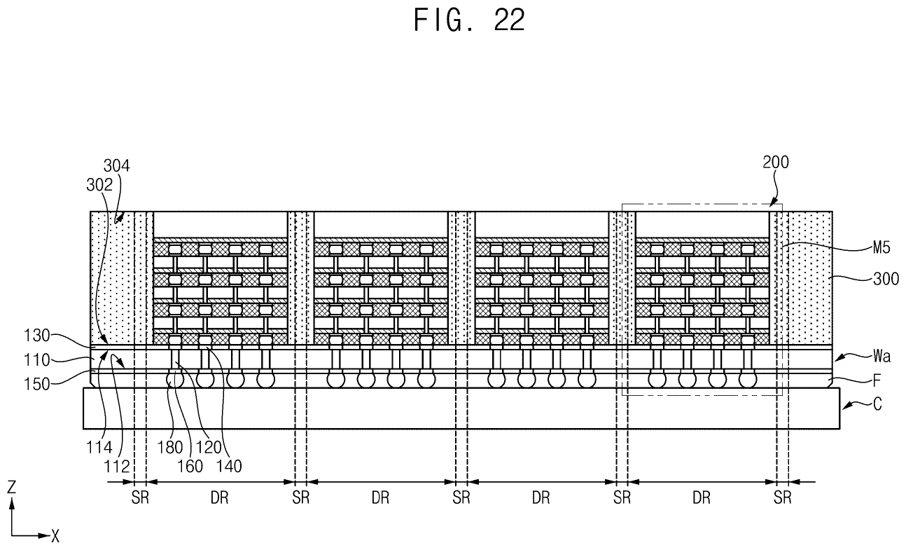

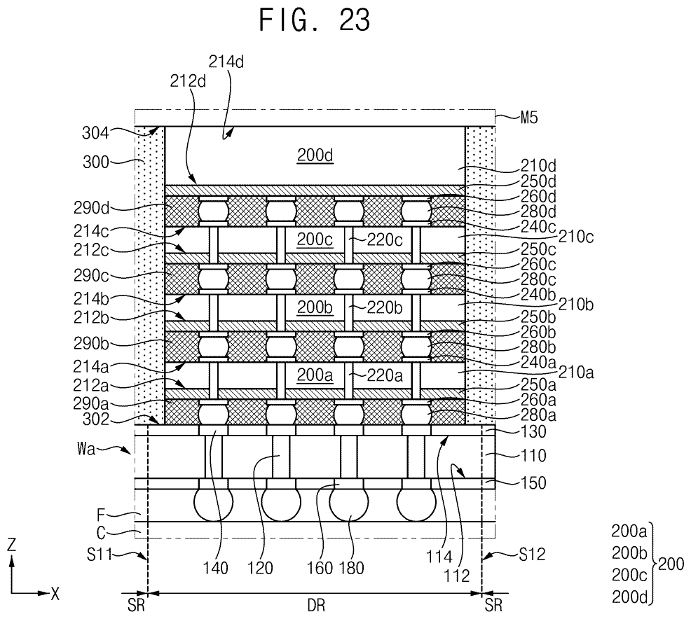

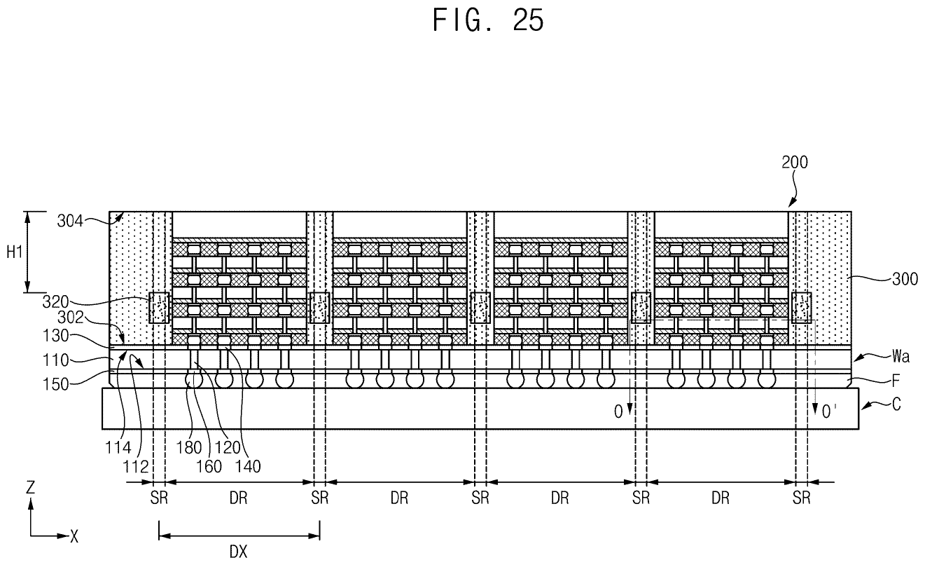

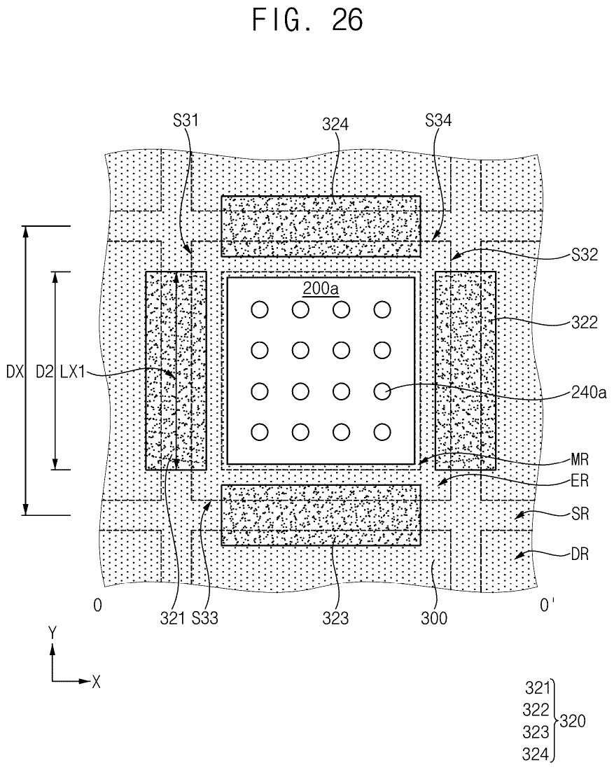

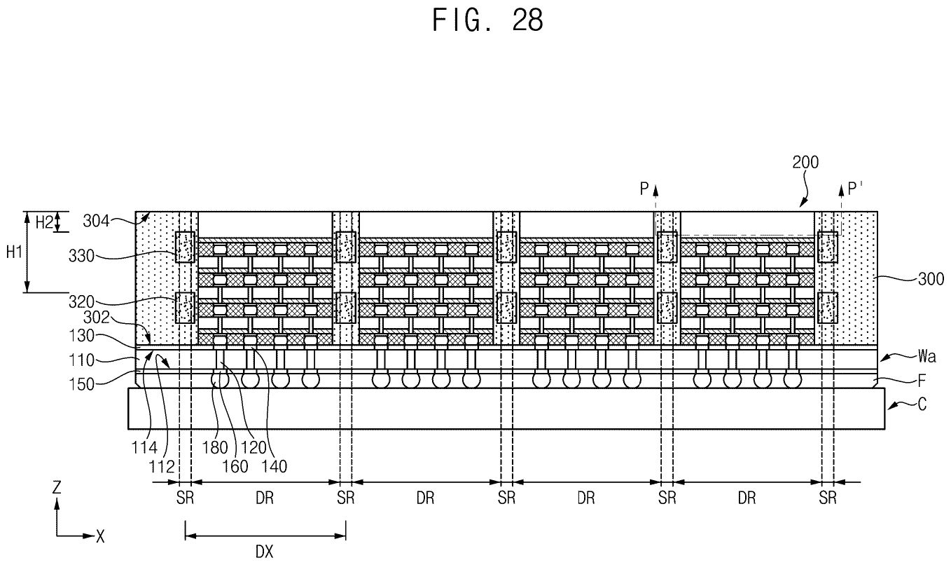

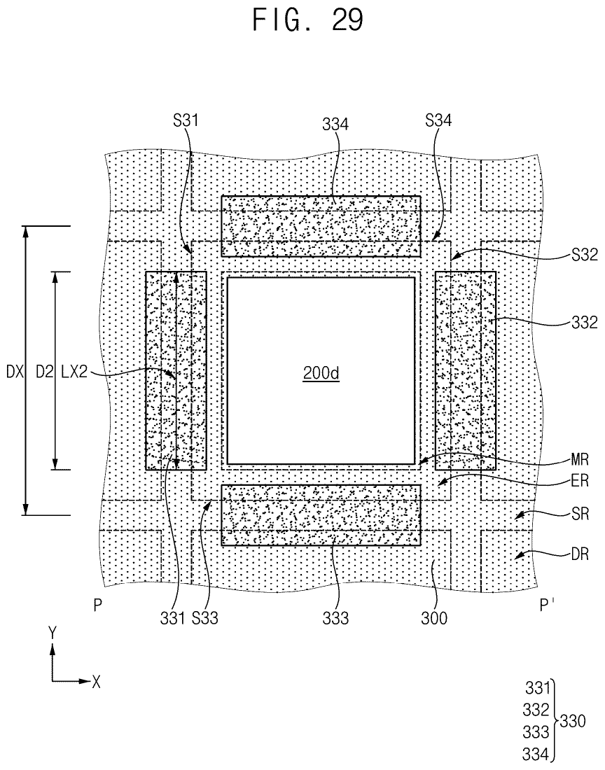

FIGS. 22 to 30 are views illustrating a method of manufacturing a semiconductor package in accordance with example embodiments. FIGS. 22, 24-25, 27-28 and 30 are cross-sectional views illustrating a method of manufacturing a semiconductor package in accordance with example embodiments. FIG. 23 is an enlarged cross-sectional view illustrating the portion ‘M5’ of FIG. 22. FIG. 26 is a cross-sectional view taken along the line O-O′ in FIG. 25. FIG. 29 is a cross-sectional view taken along the line P-P′ in FIG. 28.

The method of manufacturing the semiconductor package 11 illustrated in FIGS. 22 to 30 is substantially the same as or similar to the method of manufacturing the semiconductor package 10 described with reference to FIGS. 3 to 17 except for a method of forming a plurality of first reforming portions 320 and a plurality of second reforming portions 330. Accordingly, the same components are indicated by the same reference numerals, and repeated descriptions of the same components and the same manufacturing method will be omitted.

Referring to FIGS. 22 and 23, a plurality of semiconductor chips 200 are mounted on the wafer Wa, and then a molding member 300 may be formed to surround the plurality of semiconductor chips 200 in the same manner as the method of manufacturing the semiconductor package 10 described with reference to FIGS. 3 to 9.

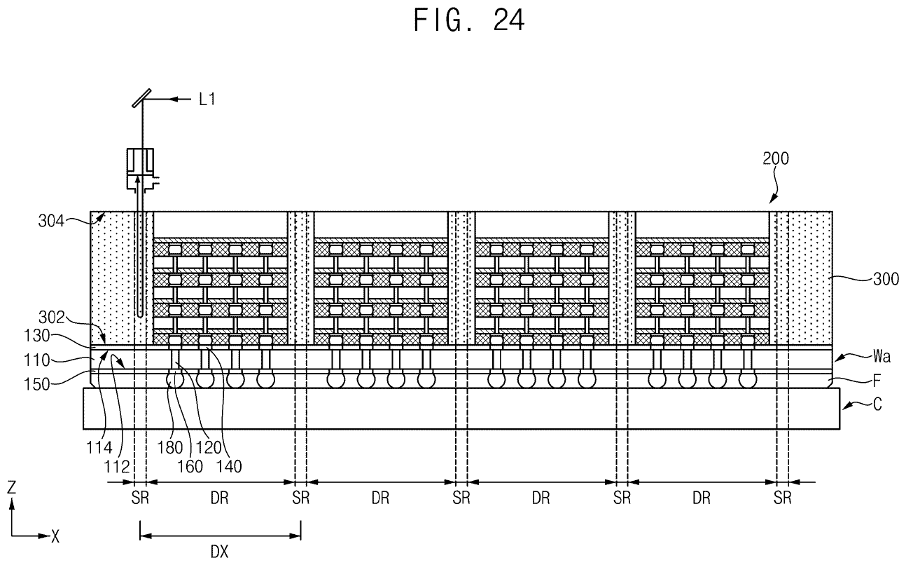

Referring to FIGS. 24 to 26, a plurality of first reforming portions 320 may be formed by irradiating a laser on a portion among the molding member 300 provided on the scribe lane region SR.

For example, the reforming process may be a process of changing the physical properties of a specific material by irradiating a laser. For example, the brittleness of an epoxy molding compound (EMC) may be increased by irradiating a laser on epoxy molding compound (EMC) that has been hardened by performing a cure process. The brittleness may be the property of being easily broken when an external force is applied to a specific material.

The plurality of first reforming portions 320 may be formed by irradiating a first laser L1 to a portion of the molding member 300 provided on the scribe lane region SR and a portion of the die region DR adjacent to the scribe lane region SR.

The first laser L1 may be focused light having a predetermined first wavelength λ1. For example, the predetermined first wavelength λ1 may be set in consideration of the physical properties of the molding member 300 and a depth at which the plurality of first reforming portions 320 are formed. For example, when forming reforming portions inside a hardened epoxy molding compound (EMC), a long wavelength may be used because there is a need to transmit an epoxy molding compound (EMC). For example, when forming the plurality of first reforming portions 320, the predetermined first wavelength λ1 may be within a range of 800 nm to 835 nm.

As illustrated in FIG. 25, the plurality of first reforming portions 320 may be spaced apart in the third direction (Z direction) from the upper surface 304 of the molding member 300 toward the wafer Wa and have a predetermined distance (i.e., a predetermined depth) from the upper surface 304 of the molding member 300. For example, the plurality of first reforming portions 320 may be spaced apart from the upper surface 304 of the molding member 300 toward the wafer Wa by a first height H1.

As illustrated in FIG. 26, the plurality of first reforming portions 320 may be formed on the scribe lane region SR and the die region DR adjacent to the scribe lane region SR. For example, a portion of the molding member 300 respectively provided on the plurality of die regions DR may include first to fourth side portions S31, S32, S33, and S34 in contact with the scribe lane region SR.

The plurality of first reforming portions 320 may be formed in the first to fourth side portions S31, S32, S33, and S34 to extend across the first to fourth side portions S31, S32, S33, and S34. For example, the plurality of first reforming portions 320 may extend in and across the first to fourth side portions S31, S32, S33, and S34 to extend to portions of the molding member 300 respectively provided on the plurality of die regions DR.

The plurality of first reforming portions 320 may include first to fourth lower reforming portions 321, 322, 323, and 324. The first to fourth lower reforming portions 321, 322, 323, and 324 may each have a first longitudinal axis LX1 extending through the center thereof and parallel to at least one of the first to fourth side portions S31, S32, S33, and S34. For example, the first lower reforming portion 321 may be parallel to the first side portion S31 and have the first longitudinal axis LX1 extending through the center (e.g., a center point) of the first lower reforming portion 321.

The first longitudinal axis LX1 may have the second length D2. For example, the second length D2 may be less than or equal to the first distance DX, which is the spacing distance between the scribe lane regions SR. For example, in the case that the second length D2 and the first distance DX are the same, the first to fourth lower reforming portions 321, 322, 323, and 324 may be connected to each other to surround the scribe lane region SR.

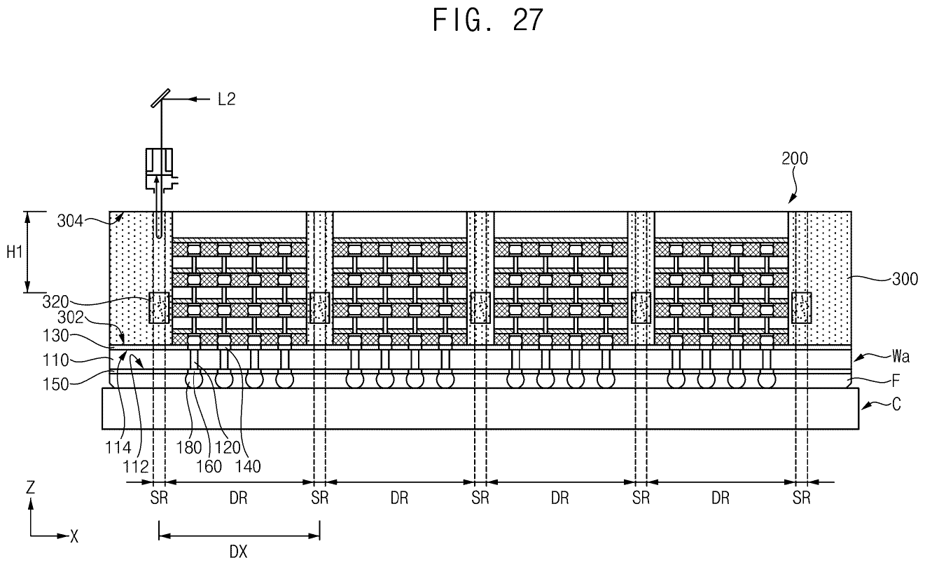

Referring to FIGS. 27 to 29, a plurality of second reforming portions 330 may be formed by irradiating a laser on a portion of the molding member 300 provided on the scribe lane region SR.

The plurality of second reforming portions 330 may be formed by irradiating a second laser L2 to a portion of the molding member 300 provided on the scribe lane region SR and a portion of the die region DR adjacent to the scribe lane region SR.

The second laser L2 may be focused light having a predetermined second wavelength λ2. For example, the predetermined second wavelength λ2 may be set in consideration of the physical properties of the molding member 300 and a depth at which the plurality of second reforming portions 330 are formed. For example, when forming reforming portions inside a hardened epoxy molding compound (EMC), a long wavelength may be used because there is a need to transmit an epoxy molding compound (EMC). For example, when forming the plurality of second reforming portions 330, the predetermined first wavelength λ2 may be within a range of 800 nm to 835 nm. For example, the second wavelength λ2 may be the same as the first wavelength λ1.

As illustrated in FIG. 28, the plurality of second reforming portions 330 may be spaced apart in the third direction (Z direction) from the upper surface 304 of the molding member 300 toward the wafer Wa and have a predetermined distance (i.e., a predetermined depth) from the upper surface 304 of the molding member 300. For example, the plurality of second reforming portions 330 may be spaced apart from the upper surface 304 of the molding member 300 toward the wafer Wa by a second height H2. For example, the second height H2 may be less than the first height H1.

In some other embodiments, the plurality of second reforming portions 330 may not be spaced apart from the upper surface 304 of the molding member 300 in the third direction (Z direction). For example, at least a portion of the plurality of second reforming portions 330 may be exposed from the upper surface 304 of the molding member 300. For example, at least a portion of an upper surface of each of the plurality of second reforming portions 330 may be coplanar with the upper surface 304 of the molding member 300. In this case, the second height (H2) may be ‘0’. In this case, the second wavelength λ2 may be within a range of 360 nm to 530 nm.

As illustrated in FIG. 29, the plurality of second reforming portions 330 may be formed on the scribe lane region SR and a portion of the die region DR adjacent to the scribe lane region SR.

The plurality of second reforming portions 330 may be formed in the first to fourth side portions S31, S32, S33, and S34 to extend across the first to fourth side portions S31, S32, S33, and S34. For example, the plurality of second reforming portions 330 may extend in and across the first to fourth side portions S31, S32, S33, and S34 to extend to portions of the molding member 300 respectively provided on each die region DR.

The plurality of second reforming portions 330 may include first to fourth upper reforming portions 331, 332, 333, and 334. The first to fourth upper reforming portions 331, 332, 333, and 334 may each have a second longitudinal axis LX2 extending through a center thereof and parallel to at least one of the first to fourth side portions S31, S32, S33, and S34. For example, the first upper reforming portion 331 may be parallel to the first side portion S31 and have the second longitudinal axis LX2 extending through the center (e.g., a center point) of the first upper reforming portion 331.

The second longitudinal axis LX2 may have the second length D2. For example, the second length D2 may be less than or equal to the first distance DX, which is the spacing distance between the scribe lane regions SR. For example, in the case that the second length D2 and the first distance DX are the same, the first to fourth upper reforming portions 331, 332, 333, and 334 may be connected to each other to surround the scribe lane region SR.

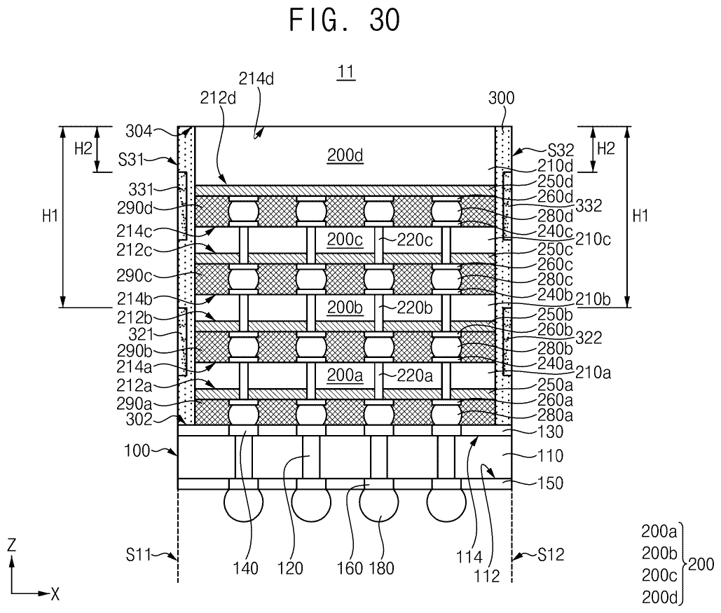

Referring to FIG. 30, the wafer Wa may be separated from the carrier substrate C, and then the wafer Wa may be cut along the scribe lane region SR to form the semiconductor package 11 in the same manner as the method of manufacturing the semiconductor package 10 described with reference to FIGS. 15 to 17.

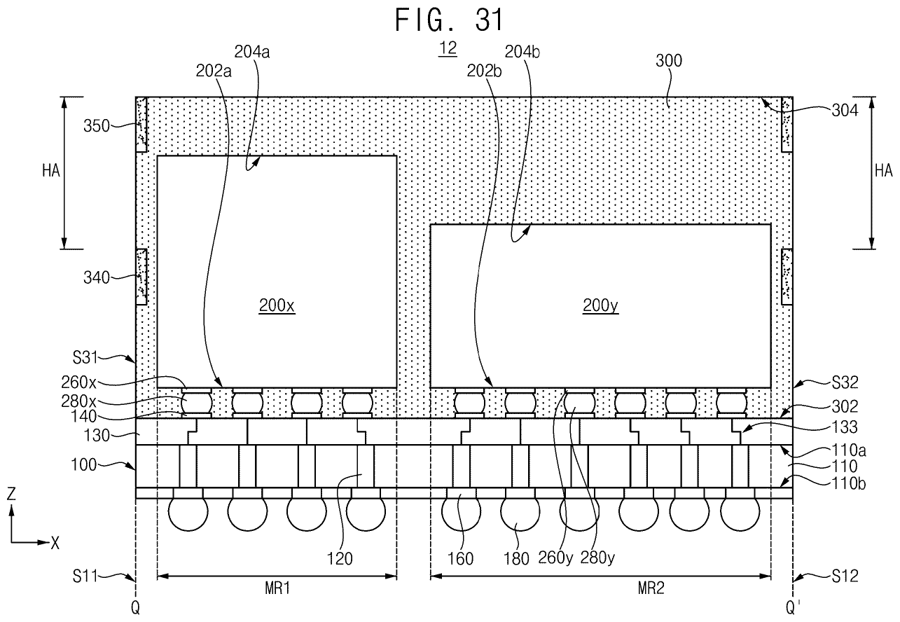

Hereinafter, a semiconductor package 12 in FIG. 31 will be described.

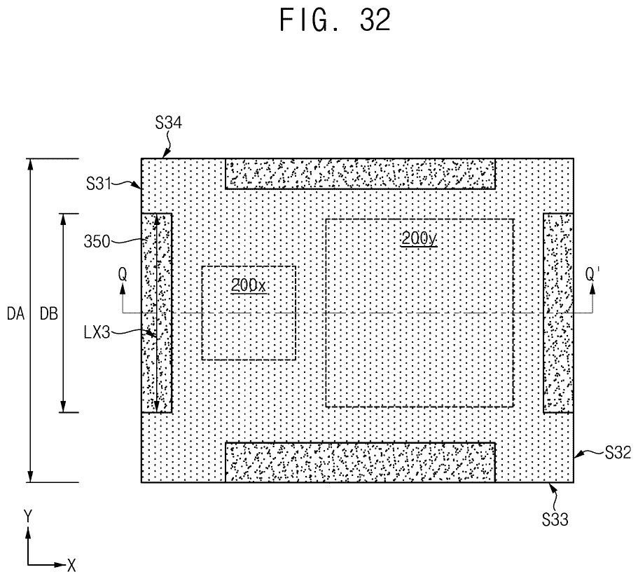

FIG. 31 is a cross-sectional view illustrating a semiconductor package in accordance with example embodiments. FIG. 32 is a plan view illustrating a semiconductor package in accordance with example embodiments. FIG. 31 is a cross-sectional view taken along the line Q-Q′ in FIG. 32.

The semiconductor package 12 is substantially the same as or similar to the semiconductor package 10 described with reference to FIGS. 1 and 2. Accordingly, the same components are indicated by the same reference numerals, and repeated descriptions of the same components and the same manufacturing method will be omitted.

Referring to FIGS. 31 and 32, the semiconductor package 12 may include the base chip 100, a plurality of electronic devices 200x and 200y stacked on the base chip 100, and a molding member 300 provided on the base chip 100 to surround the plurality of electronic devices 200x and 200y. Also, the semiconductor package 12 may further include a plurality of external connection members 180 and a plurality of conductive connection members 280 (280x, 280y). Also, the semiconductor package 12 may further include third reforming portions 340 and fourth reforming portions 350 provided on one side portion of the molding member 300. For example, the semiconductor package 12 may be a 2.5D package in which a memory device and a logic semiconductor device may be mounted on an interposer.

In example embodiments, the base chip 100 may include a base substrate 110, a plurality of conductive vias 120, an upper insulation layer 130, a plurality of upper pads 140, a plurality of lower pads 160, and a plurality of external connection members 180. For example, the base chip 100 may be an interposer that connects electrical signals between electronic devices mounted on the base chip and the package substrate on which the base chip is mounted. For example, the interposer may be a silicon interposer or a redistribution interposer having a plurality of wires formed therein.

The base chip 100 may have a first side portion S11 and a second side portion S12 parallel to the second direction (Y direction) to extend along the second direction (Y direction) (i.e., into the page in FIG. 31) perpendicular to the first direction (X direction). The base chip 100 may include a first mounting region MR1 adjacent to the first side portion S11 and a second mounting region MR2 adjacent to the second side portion S12.

The base substrate 110 may have a frontside surface 110a and a backside surface 110b opposed to each other. The frontside surface 110a may be an active surface, and the backside surface 110b may be an inactive surface. For example, the base substrate 110 may be a single crystal silicon substrate. The circuit patterns may include transistors, capacitors, diodes, etc.

The plurality of conductive vias 120 may be provided to vertically penetrate (i.e., vertically extend in) the base substrate 110 from the frontside surface 110a to the backside surface 110b of the base substrate 110. For example, the plurality of conductive vias 120 may be through silicon via (TSV). For example, the plurality of conductive vias 120 may be provided in the first mounting region MR1 and the second mounting region MR2.

The upper insulation layer 130 may be provided on the frontside surface 110a of the base substrate 110. For example, the upper insulation layer 130 may cover the frontside surface 110a of the base substrate 110. The upper insulation layer 130 may include a plurality of front wires 133 electrically connected to one end portion of each of the plurality of conductive vias 120.

The plurality of upper pads 140 may be provided on the upper insulation layer 130 to form an array along the first and second directions (X and Y directions). For example, the plurality of upper pads 140 may be in contact with the other end portion of each of the plurality of front wires 133 to be electrically connected to thereto. For example, the plurality of upper pads 140 may be conductive pads containing a metal material. For example, the plurality of upper pads 140 may be provided in the first mounting region MR1 and the second mounting region MR2.

The plurality of lower pads 160 may be provided on the backside surface 110b of the base substrate 110 to form an array along the first and second directions (X and Y directions). For example, the plurality of lower pads 160 may be in contact with an end portion of each of the plurality of conductive vias 120 to be electrically connected thereto. For example, the plurality of lower pads 160 may be conductive pads containing a metal material. For example, the plurality of lower pads 160 may be provided in the first mounting region MR1 and the second mounting region MR2.

The plurality of external connection members 180 may be respectively provided on the plurality of lower pads 160 and may be electrically connected to the plurality of lower pads 160, respectively. For example, the plurality of external connection members 180 may include solder bumps.

In example embodiments, the plurality of electronic devices 200x and 200y may include a first electronic device 200x and a second electronic device 200y. Also, the plurality of electronic devices 200x and 200y may further include a plurality of first chip pads 260x and a plurality of second chip pads 260y. Also, the plurality of electronic devices 200x and 200y may further include a plurality of first conductive bumps 280x and a plurality of second conductive bumps 280y.

The first electronic device 200x may be mounted on the first mounting region MR1 of the base chip 100. The first electronic device 200x may include a plurality of semiconductor chips. For example, the first electronic device 200x may be a high bandwidth memory (HBM) device in which a plurality of semiconductor chips are sequentially stacked.

The first electronic device 200x may be mounted on the first mounting region MR1 as a flip chip method. The first electronic device 200x may have a lower surface 202a and an upper surface 204a facing each other (i.e., opposing each other). The first electronic device 200x may include a plurality of first chip pads 260x on the lower surface 202a. For example, the first electronic device 200x may mounted on the mounting region MR1 via the plurality of first conductive bumps 280x respectively provided between the plurality of first chip pads 260x and the plurality of upper pads 140.

The second electronic device 200y may be mounted on the second mounting region MR2 of the base chip 100 and may be spaced apart from the first electronic device 200x along the first direction (X direction). For example, the second electronic device 200y may be a logic semiconductor device. The logic semiconductor device may be an ASIC as a host, such as a CPU, GPU, or SoC.

The second electronic device 200y may be mounted on the second mounting region MR2 as a flip chip method. The second electronic device 200y may have a lower surface 202b and an upper surface 204b facing each other (i.e., opposing each other). The second electronic device 200y may include a plurality of second chip pads 260y on the lower surface 202b. For example, the second electronic device 200y may be mounted on the mounting region MR2 via a plurality of second conductive bumps 280y respectively provided between the plurality of second chip pads 260y and the plurality of upper pads 140.

In example embodiments, the molding member 300 may be provided on the base chip 100 to surround the first electronic device 200x and the second electronic device 200y. For example, the molding member 300 may include an epoxy molding compound (EMC).

The molding member 300 may have a lower surface 302 in contact with the base chip 100 and an upper surface 304 facing (i.e., opposing) the lower surface 302. The molding member 300 may be provided with first to fourth side portions S31, S32, S33, and S34 extending in the third direction (Z direction) between the upper surface 304 and the lower surface 302. The first and second side portions S31 and S32 may have a third length DA in the second direction (Y direction). Also, the third and fourth side portions S33 and S34 may have a third length DA in the first direction (X direction).

In example embodiments, the third reforming portions 340 and fourth reforming portions 350 may be provided in at least one side portion of the molding member 300.

For example, the plurality of third reforming portions 340 and the plurality of fourth reforming portions 350 may be provided in the first to fourth side portions S31, S32, S33 and S34. A portion of each of the plurality of third reforming portions 340 and a portion of each of the plurality of fourth reforming portions 350 may be exposed from a respective one of the first to fourth side portions S31, S32, S33 and S34 of the molding member 300. For example, the plurality of third and fourth reforming portions 340 and 350 may include a material that is more brittle than the molding member 300. The brittleness may be the property of being easily broken when an external force is applied to a specific material. Each of the plurality of third reforming portions 340 and each of the plurality of fourth reforming portions 350 may extend horizontally in a respective one of the first to fourth side portions S31, S32, S33, and S34 to have a predetermined width from a respective outer side surface of the molding member 300. For example, each of the plurality of third reforming portions 340 and each of the plurality of fourth reforming portions 350 may have a side surface that is coplanar with a respective outer side surface of the molding member 300. The plurality of third reforming portions 340 and the plurality of fourth reforming portions 350 may be spaced apart from the plurality of electronic devices 200x and 200y by a predetermined distance.

The plurality of third reforming portions 340 may be spaced apart from the upper surface 304 of the molding member 300 along the third direction (Z direction) by a predetermined distance HA (i.e., a predetermined depth HA). For example, the plurality of third reforming portions 340 may be spaced apart from the upper surface 304 toward the base chip 100 along the third direction (Z direction).

A portion of each of the plurality of fourth reforming portions 350 may be exposed from the upper surface 304 of the molding member 300 (i.e., may be free of the upper surface 304 of the molding member 300 thereon). For example, an upper surface of each of the plurality of fourth reforming portions 350 may be coplanar with the upper surface 304 of the molding member 300. Also, the plurality of fourth reforming portions 350 may be spaced apart from the plurality of third reforming portions 340 in the third direction (Z direction). For example, the plurality of fourth reforming portions 350 may be spaced apart from the plurality of third reforming portions 340 along the third direction (Z direction) opposite to the base chip 100. For example, the plurality of fourth reforming portions 350 may respectively overlap the plurality of third reforming portions 340 in the third direction (Z direction).

The plurality of third reforming portions 340 and the plurality of fourth reforming portions 350 may respectively have a third longitudinal axis LX3 passing through the center (e.g., a center point) thereof parallel to a respective one of the first to fourth side portion S31, S32, S33, and S34.

The third longitudinal axis LX3 may have a fourth length DB. For example, the fourth length DB may be less than or equal to the third length DA of the first to fourth side portions S31, S32, S33 and S34. For example, when the third length DA and the fourth length DB are the same, the plurality of third reforming portions 340 and the plurality of fourth reforming portions 350 may be respectively connected to each other to surround the first to fourth side portions S31, S32, S33, and S34.

Hereinafter, a method of manufacturing the semiconductor package of FIG. 12 will be described.

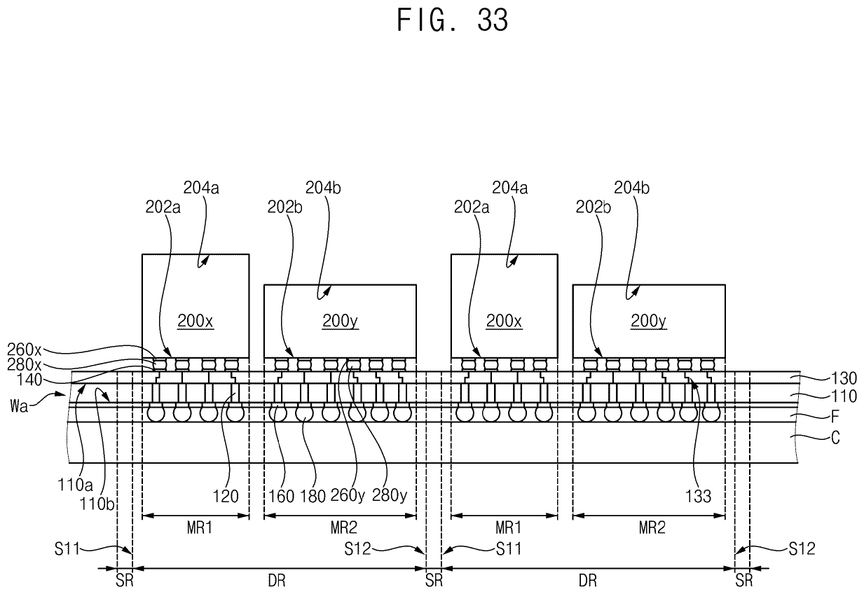

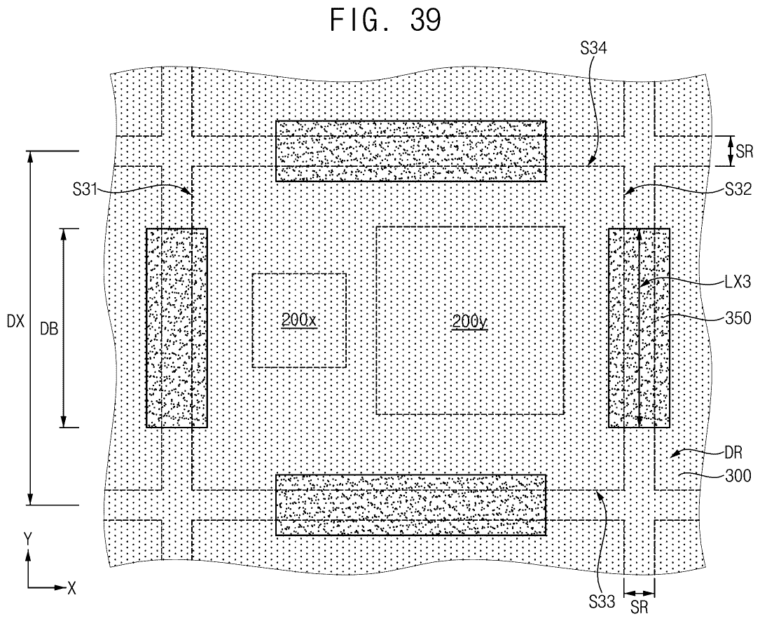

FIGS. 33 to 40 are views illustrating a method of manufacturing a semiconductor package in accordance with example embodiments. FIGS. 33 to 38 and FIG. 40 are cross-sectional views illustrating a method of manufacturing a semiconductor package in accordance with example embodiments. FIG. 39 is a plan view illustrating a plurality of fourth reforming portions of a semiconductor package in accordance with example embodiments.

The method of manufacturing the semiconductor package 12 illustrated in FIGS. 33 to 40 is substantially the same as or similar to the method of manufacturing the semiconductor package 10 described with reference to FIGS. 3 to 17. Accordingly, the same components are indicated by the same reference numerals, and repeated descriptions of the same components and the same manufacturing method will be omitted.

Referring to FIG. 33, a first electronic device 200x and a second electronic device 200y may be respectively mounted on the first mounting region MR1 and the second mounting region MR2 provided in the die region DR of the wafer Wa. For example, the wafer Wa may include a plurality of base chips 100. The base chip may be substantially the same as the base chip 100 as an interposer described with reference to FIGS. 31 and 32.

The first electronic device 200x may be mounted on the first mounting region MR1 of the base chip 100. The first electronic device 200x may include a plurality of semiconductor chips. For example, the first electronic device 200x may be a high bandwidth memory (HBM) device in which a plurality of semiconductor chips are sequentially stacked.

The first electronic device 200x may be mounted on the first mounting region MR1 as a flip chip method. For example, the first electronic device 200x may be mounted on the mounting region MR1 via a plurality of first conductive bumps 280x respectively provided between a plurality of first chip pads 260x and a plurality of upper pads 140.

The second electronic device 200y may be mounted on the second mounting region MR1 of the base chip 100 and may be spaced apart from the first electronic device 200x along the first direction (X direction). For example, the second electronic device 200y may be a logic semiconductor device. The logic semiconductor device may be an ASIC as a host, such as a CPU, GPU, or SoC.

The second electronic device 200y may be mounted on the second mounting region MR2 as a flip chip method. For example, the second electronic device 200y may be mounted on the mounting region MR2 via a plurality of second conductive bumps 280y respectively provided between the plurality of second chip pads 260y and the plurality of upper pads 140.

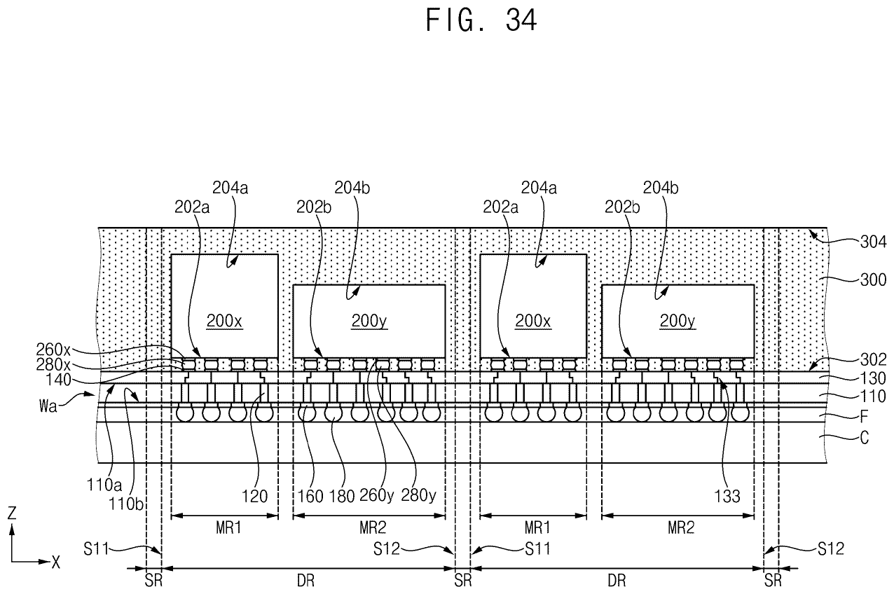

Referring to FIG. 34, a molding member 300 may be formed on the wafer Wa to surround the first electronic device 200x and the second electronic device 200y. For example, the molding member 300 may be on (e.g., may cover) both side portions (i.e., opposing side portions), an upper surface and a lower surface (which may collectively be referred to as outer surfaces) of the first electronic device 200x and the second electronic device 200y.

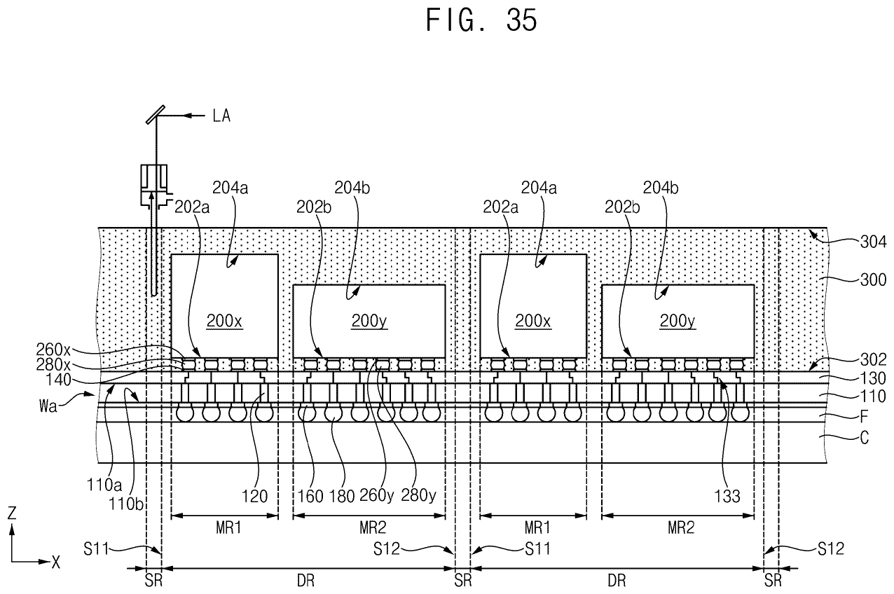

Referring to FIGS. 35 to 39, a plurality of third reforming portions 340 and a plurality of fourth reforming portions 350 may be formed by irradiating a laser on the scribe lane region SR of the molding member 300.

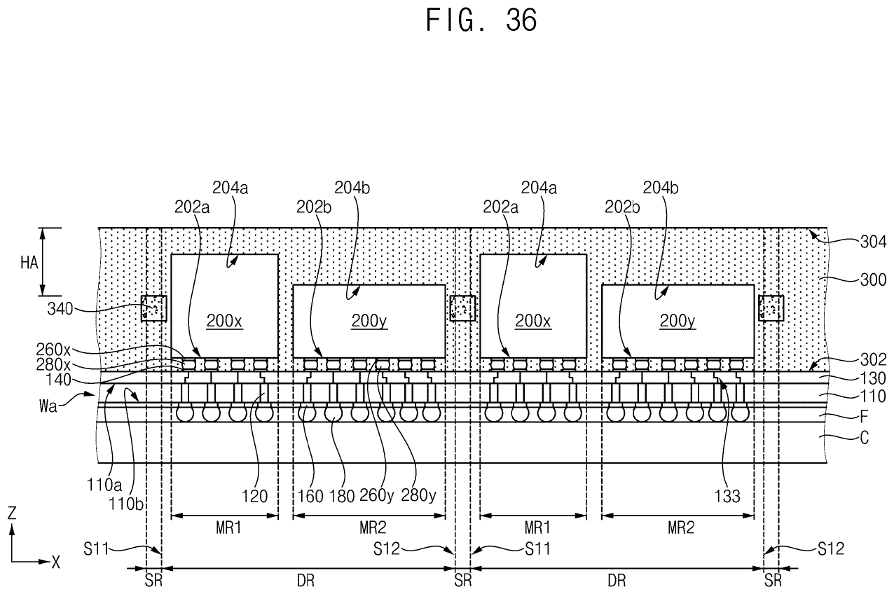

As illustrated in FIGS. 35 and 36, a plurality of third reforming portions 340 may be formed by irradiating a third laser LA on the scribe lane region SR of the molding member 300. For example, the third laser LA may be focused light having a predetermined third wavelength λ3. For example, the predetermined third wavelength λ3 may be set in consideration of the physical properties of the molding member 300 and a depth at which the plurality of third reforming portions 340 are formed. For example, when forming the plurality of third reforming portions 340 inside a hardened epoxy molding compound (EMC), the predetermined third wavelength λ3 may be within a range of 800 nm to 835 nm.

The plurality of third reforming portions 340 may be formed inside the molding member 300 to have a predetermined height from the upper surface 304 of the molding member 300. The predetermined height may have a third height HA.

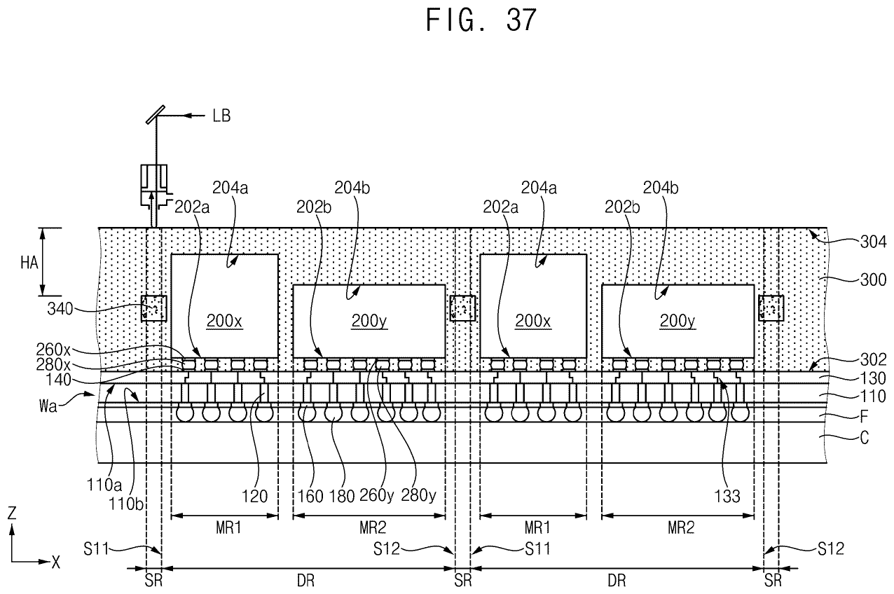

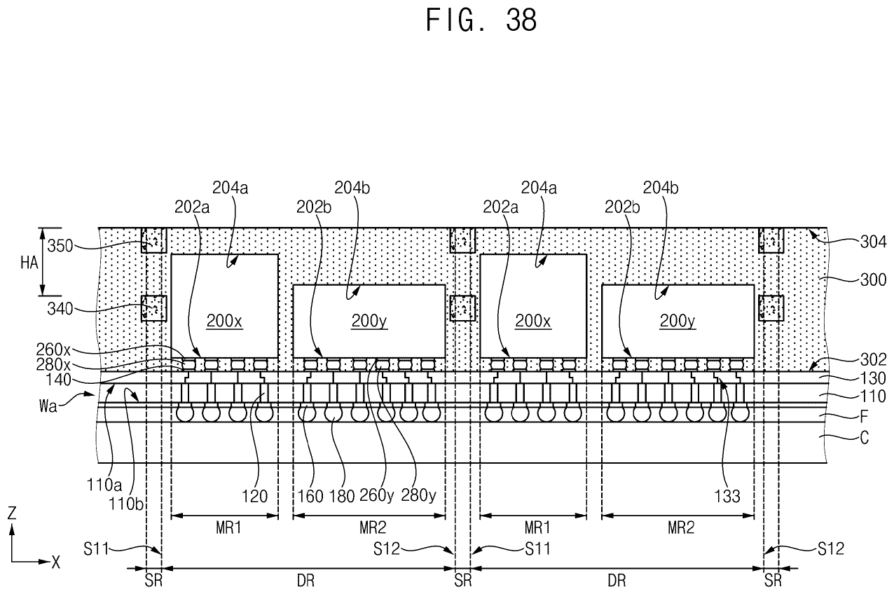

As shown in FIGS. 37 and 38, a plurality of fourth reforming portions 350 may be formed by irradiating a fourth laser LB on the scribe lane region SR of the molding member 300. For example, the fourth laser LB may be focused light having a predetermined fourth wavelength λ4. For example, the predetermined fourth wavelength λ4 may be set in consideration of the physical properties of the molding member 300 and a depth at which the plurality of fourth reforming portions 350 are formed. For example, when forming the plurality of fourth reforming portions 350 inside a hardened epoxy molding compound (EMC), the predetermined fourth wavelength λ4 may be within a range of 360 nm to 530 nm.

The plurality of fourth reforming portions 350 may be formed in the molding member 300 such that a portion of each of the plurality of fourth reforming portions 350 may be exposed from the upper surface 304 of the molding member 300 (i.e., may be free of the upper surface 304 of the molding member 300 thereon).

As shown in FIG. 39, the plurality of third reforming portions 340 and the plurality of fourth reforming portions 350 may be provided on the scribe lane region SR. Although only the plurality of fourth reforming portions 350 are shown in FIG. 39, the plurality of third reforming portions 340 may also be substantially the same as the plurality of fourth reforming portions 350.

Each of the plurality of fourth reforming portions 350 may have a third longitudinal axis LX3 passing through the center (e.g., a center point) thereof parallel to the scribe lane region SR. For example, the die region DR of the wafer Wa may include first to fourth side portions S31, S32, S33, and S34, respectively. The plurality of fourth reforming portions 350 may be formed in the first to fourth side portions S31, S32, S33, and S34 of the die region DR.

The distance between the scribe lane regions SR surrounding the die region DR may have a first distance DX. The third longitudinal axis LX3 may have a fourth length DB. For example, the fourth length DB may be less than or equal to the first distance DX. For example, when the first distance DX and the fourth length DB are the same, the plurality of third reforming portions 340 and the plurality of fourth reforming portions 350 may be respectively connected to each other to surround the scribe lane region SR.

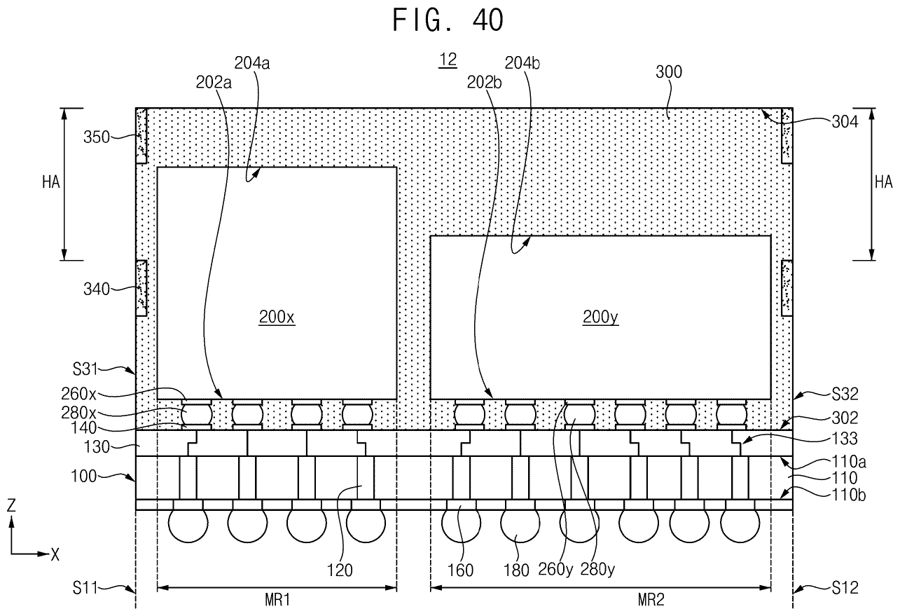

Referring to FIG. 40, the wafer Wa may be separated from the carrier substrate C, and then the wafer Wa may be cut along the scribe lane region SR to form the semiconductor package 12. The semiconductor package 12 can be formed by cutting along in the same manner as the method of manufacturing the semiconductor package 10 described with reference to FIGS. 15 to 17.

The semiconductor package 12 may include semiconductor devices such as logic devices or memory devices. The semiconductor package 12 may include logic devices such as central processing units (CPUs), main processing units (MPUs), or application processors (Aps), or the like, and volatile memory devices such as DRAM devices, HBM devices, or non-volatile memory devices such as flash memory devices, PRAM devices, MRAM devices, ReRAM devices, or the like.

As used herein, it will be understood that the terms “comprises”, “comprising”, “includes”, “including”, “has”, “having” and any other variations thereof specify the presence of the stated features, steps, operations, elements, components, and/or groups but do not preclude the presence or addition of one or more other features, steps, operations, elements, components, and/or groups thereof.

The foregoing is illustrative of example embodiments and is not to be construed as limiting thereof. Although a few example embodiments have been described, those skilled in the art will readily appreciate that many modifications are possible in example embodiments without materially departing from the scope of the present disclosure. Accordingly, all such modifications are intended to be included within the scope of example embodiments as defined in the claims.

What is claimed is:

1. A semiconductor package, comprising:
a substrate structure;
a plurality of semiconductor chips sequentially stacked on the substrate structure;
a molding member on the substrate structure and surrounding side surfaces of the plurality of semiconductor chips, the molding member comprising a first material; and
a first reforming portion in a side portion of the molding member, and extending horizontally in the side portion of the molding member to have a predetermined width from an outer side surface of the molding member,
wherein the first reforming portion comprises a second material that is more brittle than the first material.

2. The semiconductor package of claim 1, wherein at least a portion of the first reforming portion is not covered by an upper surface of the molding member.

3. The semiconductor package of claim 1, wherein the second material of the first reforming portion comprises a laser-irradiated material.

4. The semiconductor package of claim 1, wherein the first reforming portion has a predetermined depth from an upper surface of the molding member.

5. The semiconductor package of claim 4, further comprising:
a second reforming portion in the side portion of the molding member and spaced apart from the first reforming portion along a vertical direction, the second reforming portion extending horizontally in the side portion of the molding member to have the predetermined width from the outer side surface of the molding member,
wherein the second reforming portion comprises the second material that is more brittle than the first material.

6. The semiconductor package of claim 5, wherein the second material of the second reforming portion comprises a laser-irradiated material.

7. The semiconductor package of claim 1, wherein a side surface of the first reforming portion and the outer side surface of the molding member are coplanar with each other.

8. The semiconductor package of claim 1, wherein the first reforming portion is spaced apart from the plurality of semiconductor chips by a predetermined distance, and at least a portion of the first reforming portion is not covered by the molding member.

9. The semiconductor package of claim 1, wherein a lower surface of the molding member is in contact with an upper surface of the substrate structure.

10. The semiconductor package of claim 1, wherein the plurality of semiconductor chips are sequentially stacked on the substrate structure via a plurality of conductive bumps.

11. A semiconductor package, comprising:
a substrate structure having a first mounting region and a second mounting region that is spaced apart from the first mounting region along a first horizontal direction;
a first electronic device stacked on the first mounting region of the substrate structure;
a second electronic device stacked on the second mounting region of the substrate structure;
a molding member on the substrate structure and surrounding outer surfaces of the first electronic device and outer surfaces of the second electronic device, the molding member comprising a first material; and
a first reforming portion in a side portion of the molding member, and extending horizontally in the side portion of the molding member to have a predetermined width from an outer side surface of the molding member,
wherein the first reforming portion comprises a second material that is more brittle than the first material.

12. The semiconductor package of claim 11, wherein at least a portion of the first reforming portion is not covered by an upper surface of the molding member.

13. The semiconductor package of claim 11, wherein the second material of the first reforming portion comprises a laser-irradiated portion of the molding member.

14. The semiconductor package of claim 11, further comprising:
a second reforming portion in the side portion of the molding member and spaced apart from the first reforming portion along a vertical direction, the second reforming portion extending horizontally in the side portion of the molding member to have the predetermined width from the outer side surface of the molding member,
wherein the second reforming portion comprises the second material that is more brittle than the first material.

15. The semiconductor package of claim 14, wherein the second material of the second reforming portion comprises a laser-irradiated portion of the molding member.

16. The semiconductor package of claim 11, wherein a side surface of the first reforming portion and the outer side surface of the molding member are coplanar with each other.

17. The semiconductor package of claim 11, wherein the first reforming portion is spaced apart from the first electronic device and the second electronic device by a predetermined distance, and at least a portion of the first reforming portion is not covered by the molding member.

18. The semiconductor package of claim 11, wherein a lower surface of the molding member is in contact with an upper surface of the substrate structure.

19. The semiconductor package of claim 11, wherein the first electronic device includes a plurality of semiconductor chips stacked on the first mounting region of the substrate structure, and
wherein the second electronic device includes at least one semiconductor chip stacked on the second mounting region of the substrate structure.

20. A semiconductor package, comprising:
a substrate structure;
a plurality of semiconductor chips sequentially stacked on the substrate structure;
a molding member on the substrate structure and surrounding side surfaces of the plurality of semiconductor chips, the molding member comprising a first material;
a first reforming portion in a side portion of the molding member, and extending horizontally in the side portion of the molding member to have a predetermined width from an outer side surface of the molding member; and
a second reforming portion in the side portion of the molding member and spaced apart from the first reforming portion along a vertical direction so that the second reforming portion is closer to the substrate structure than the first reforming portion, the second reforming portion extending horizontally in the side portion of the molding member to have the predetermined width from the outer side surface of the molding member,
wherein the first reforming portion and the second reforming portion comprise a second material that is more brittle than the first material.
